(19) United States
(12) Patent Application Publication
(10) Pub. No.: US 2025/0166989 A1
(43) Pub. Date: May 22, 2025

(54) THERMAL FILM DEPOSITION

(71) Applicant: Lam Research Corporation, Fremont, CA (US)

(72) Inventors: Jason Alexander Varnell, Tigard, OR (US); Dustin Zachary Austin, Tigard, OR (US); Praneeth Ramasagaram, Boise, ID (US); Bart J. van Schravendijk, Palo Alto, CA (US); Jennifer Leigh Petraglia, Lake Oswego, OR (US); Douglas Walter Agnew, Portland, OR (US); Awnish Gupta, Hillsboro, OR (US); Pei-Chi Liu, Portland, OR (US); Pulkit Agarwal, Beaverton, OR (US)

(21) Appl. No.: 18/840,453

(22) PCT Filed: Feb. 21, 2023
(86) PCT No.: PCT/US2023/013525

§ 371 Date: Aug. 21, 2024

Related U.S. Application Data
(60) Provisional application No. 63/378,018, filed on Sep. 30, 2022.
(60) Provisional application No. 63/377,307, filed on Sep. 27, 2022.
(60) Provisional application No. 63/268,342, filed on Feb. 22, 2022.
(60) Provisional application No. 63/268,338, filed on Feb. 22, 2022.

(51) Int. Cl. H01L 21/02

(52) U.S. Cl. CPC H01L 21/02274; H01L 21/02164; H01L 21/02211; H01L 21/0228; H01L 21/02323; H01L 21/02329; H01L 21/0234

(57) ABSTRACT

Methods and apparatuses for depositing superconformal dielectric material using thermal chemical vapor deposition-enhanced atomic layer deposition are provided. Methods and apparatuses for depositing material using modified atomic layer deposition integrating pyrolyzing a deposition precursor such as an aminosilane during dose to form a pyrolyzed layer, optional inert gas plasma for densification, and an oxygen-containing or nitrogen-containing plasma to convert the pyrolyzed layer into an oxygen-containing or nitrogen-containing material.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor fabrication processes involve deposition of silicon-containing materials, including silicon oxide materials. It is challenging to deposit silicon oxide into large features while maintaining high throughput and conformality using some techniques.

Semiconductor processing involves thin film deposition using certain atomic layer deposition precursors. In some processes, gapfill applications may be relevant. However, some gapfill processes may result in the formation of seams, or may cause densification, bending, poor cross-linking, or generally lower quality films.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method of processing a substrate, the method including: (a) introducing a deposition precursor to a process chamber housing the substrate; (b) introducing a plasma to the process chamber, the plasma being generated from igniting a reactant to form a reactant plasma ambient in the process chamber; and (c) while the reactant plasma ambient is in the process chamber, introducing the deposition precursor to the process chamber to form at least a partial film on the substrate.

In various embodiments, the plasma is generated by introducing the reactant to the process chamber and igniting the reactant in situ.

In various embodiments, the method further includes (d) when introducing the deposition precursor to the process chamber, introducing the reactant to the process chamber.

In various embodiments, the method further includes repeating (a) and (b) in cycles.

Another aspect involves method of processing a substrate, the method including: (a) introducing a deposition precursor to a process chamber housing the substrate; (b) introducing a plasma to the process chamber, the plasma being generated from igniting a reactant to form a reactant plasma ambient in the process chamber; and (c) during the introducing of the deposition precursor to the process chamber, introducing the reactant to the process chamber to form at least a partial film on the substrate.

In various embodiments, the deposition precursor is introduced thermally in at least one of (a) and (b).

In various embodiments, the method further includes partially purging the process chamber after (b) and before (c).

In various embodiments, the method further includes purging the process chamber after (a) and before (b).

In various embodiments, the plasma is generated remotely.

In various embodiments, the plasma is generated in situ.

Another aspect involves a method of processing a substrate, the method including: (a) introducing a deposition precursor to a process chamber housing the substrate; (b) optionally purging the process chamber; (c) introducing a plasma generated from igniting a reactant to form a reactant plasma ambient and form a partial film on the substrate; (d) optionally partially purging the process chamber; (e) introducing the deposition precursor to the process chamber while the reactant plasma ambient is maintained in the process chamber to form additional film on the substrate; and (f) optionally purging the process chamber.

Another aspect involves a method of processing a substrate, the method including: (a) introducing a reactant to a process chamber housing the substrate at a first flow rate; (b) generating a plasma by igniting the reactant; and (c) change flow rate of the reactant and introduce a deposition precursor to the process chamber to cause the reactant to react with the deposition precursor to form a film on a surface of the substrate.

Another aspect involves a method of processing a substrate, the method including: (a) introducing a reactant to a process chamber housing the substrate; (b) generating a plasma by igniting the reactant; and (c) while the reactant is continuously introduced, introducing a deposition precursor to the process chamber to react the deposition precursor with the reactant to form a film on a surface of the substrate.

Another aspect involves a method of processing a substrate, the method including: (a) introducing a reactant to a process chamber housing the substrate; (b) generating a plasma by igniting the reactant; (c) stopping generation of the plasma; and (d) after stopping the generation of the plasma, introducing both the reactant and a deposition precursor to the process chamber to react the deposition precursor with the reactant to form a film on a surface of the substrate.

In various embodiments, the deposition precursor is silicon-containing precursor. For example, in some embodiments, the silicon-containing precursor is an aminosilane.

In various embodiments, the process chamber includes a pedestal holding the substrate, and the pedestal is heated to a temperature of at least about 500° C.

In various embodiments, the deposition precursor is introduced in at least one operation without igniting a plasma.

In various embodiments, the reactant is an oxidizer.

One aspect involves a method for processing substrates, the method including: pyrolyzing a deposition precursor on a surface of a substrate to form a pyrolyzed film; and exposing the pyrolyzed film to a first plasma to form a deposited film. In various embodiments, the pyrolyzing is performed by heating the substrate to a temperature sufficient to cause pyrolysis of the deposition precursor; and exposing the surface of the substrate to the deposition precursor.

In various embodiments, the pyrolyzing and the exposing of the pyrolyzed film are performed in a process chamber having a chamber pressure of about 10 Torr to about 60 Torr.

In various embodiments, exposing the pyrolyzed film to a plasma includes exposing the pyrolyzed film to an inert gas plasma and then exposing the pyrolyzed film to an oxygen-containing or nitrogen-containing plasma.

In various embodiments, the method also includes repeating pyrolyzing the deposition precursor and exposing the pyrolyzed film to the plasmas.

Another aspect involves a method for processing substrates, the method including: setting a temperature of a heatable pedestal holding a substrate to a first temperature; exposing the substrate to a deposition precursor having a pyrolysis temperature that is less than the substrate temperature while the pedestal is heated to the first temperature in a plasma-free environment; stopping exposure of the deposition precursor; and after stopping exposure of the deposition precursor, exposing the substrate to a first plasma to form a deposited film.

In various embodiments, the deposition precursor is di(isopropylamino)silane.

In various embodiments, the deposition precursor is bis(tertiarybutylamino)silane.

In various embodiments, the method also includes exposing the pyrolyzed film to a second plasma.

In various embodiments, the first plasma is generated by igniting an inert gas and the deposited film is densified. In some embodiments, the inert gas is one or more of hydrogen, helium, argon, nitrogen, and xenon.

In various embodiments, the first plasma is generated by igniting an oxygen-containing or nitrogen-containing gas and the deposited film is an oxide or nitride. In some embodiments, the second plasma is generated by igniting an oxygen-containing or nitrogen-containing gas and the deposited film is an oxide or nitride.

In various embodiments, the oxygen-containing gas is one or more of oxygen, nitrous oxide, carbon dioxide, ozone, and peroxides.

In various embodiments, the nitrogen-containing gas is one or more of nitrogen gas and ammonia.

Another aspect involves an apparatus for processing substrates, the apparatus including: one or more process chambers, each process chamber including a heated pedestal; one or more gas inlets into the process chambers and associated flow-control hardware; a plasma generator; and a controller having at least one processor and a memory, whereby the at least one processor and the memory are communicatively connected with one another, the at least one processor is at least operatively connected with the flow-control hardware, and the memory stores computer-executable instructions for controlling the at least one processor to at least control the flow-control hardware to: cause heating of the pedestal; cause introduction of a deposition precursor to the one or more process chambers for a duration sufficient to cause pyrolysis of the pyrolysis precursor on a substrate on the pedestal when heated without igniting a plasma; cause generation of an inert gas plasma; and cause generation of a plasma using an oxygen-containing or nitrogen-containing gas.

In various embodiments, the instructions further cause the pedestal to be heated to a temperature of at least 400° C.

In various embodiments, the instructions further cause repeating of introduction of the deposition precursor and generation of the plasma using an oxygen-containing or nitrogen-containing gas in temporally separated pulses.

In various embodiments, the instructions further cause repeating of introduction of the deposition precursor and generation of the inert gas plasma.

In various embodiments, the plasma generator generates plasmas within one of the one or more process chambers.

These and other aspects are described further below with reference to the drawings.

### BRIEF DESCRIPTION OF THE DRAWINGS

FIGS. 1A-IC are process flow diagrams depicting operations that may be performed in accordance with certain disclosed embodiments.

FIG. 1D is a process flow diagram depicting operations performed in accordance with certain disclosed embodiments.

FIG. 1E shows two schematic illustrations of features before and after oxidation.

FIG. 2 is a schematic diagram of an example process chamber for performing certain disclosed embodiments.

FIG. 3 is a schematic diagram of an example process tool for performing certain disclosed embodiments.

FIG. 4 is a schematic diagram of an example process tool for performing certain disclosed embodiments.

FIG. 5A is a graph showing wet etch rate versus stress for various silicon oxide films deposited using certain disclosed embodiments.

FIG. 5B is a graph showing the RF power used during conversion versus the stress for various silicon oxide films deposited using certain disclosed embodiments.

FIG. 6 is an FTIR of films deposited using certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often involve various deposition processes.

Semiconductor processing involves deposition of films into features of varying topography, which may include high aspect ratio features and horizontal features. Some deposition techniques may cause the formation of a seam in features due to the small size of the feature opening. The formation of the seam may cause the density of the film material in that region to be reduced compared to the density of the film in the rest of the deposited material.

For example, sometimes, atomic layer deposition (ALD) is used to deposit material into features with small feature openings.

In some implementations, semiconductor fabrication processes may involve deposition of material into large gaps, which may be performed by chemical vapor deposition (CVD) or plasma-enhanced CVD (PECVD). Large gaps may be defined as being greater than about 0.5 μm to about 1 μm wide and having low aspect ratios, such as less than about 15:1 or less than about 10:1 or less than about 5:1 or less than about 3:1. In some applications, such as formation of 3D-NAND structures, scaling such lower aspect ratios may increase and void-free deposition into large gaps becomes challenging. One method for depositing films in such way to avoid formation of voids is by performing atomic layer deposition (ALD).

ALD is a technique that deposits thin layers of material using sequential self-limiting reactions. ALD processes use surface-mediated deposition reactions to deposit films on a layer-by-layer basis in cycles. As an example, an ALD cycle may include the following operations: (i) delivery/adsorption of a precursor, (ii) purging of precursor from the chamber, (iii) delivery of a second reactant and optionally ignite plasma, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc. In ALD deposition of silicon oxide films, this reaction involves reacting oxygen plasma with carbon and nitrogen to form a gaseous species; oxidizing silicon to silicon oxide; eliminating trace carbon, nitrogen, and hydrogen impurities; and increasing bonding and densification of the film.

Unlike a chemical vapor deposition (CVD) technique, ALD processes use surface-mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physisorbed molecules of the first precursor. It should be understood that when a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas, is introduced to the chamber so that some of these molecules react with the first precursor adsorbed on the surface. In some processes, the second precursor reacts immediately with the adsorbed first precursor. In other embodiments, the second reactant reacts only after a source of activation is applied temporally. The chamber may then be evacuated again to remove unbound second reactant molecules. As described above, in some embodiments the chamber may not be completely evacuated. Additional ALD cycles may be used to build film thickness.

In some implementations, the ALD methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

However, while ALD or plasma-enhanced ALD (PEALD) may be used, the overall process may be slower than desired for practical implementations and due to the slow throughput, can be expensive. Such processes may also use high amounts of chemistry and might not necessarily be industrially feasible. While some techniques that incorporate thermal CVD with radio frequency (RF) plasma densification may be used, such processes might not necessarily be implementable at higher aspect ratios or in features with reentrancy in the sidewall profile, and thus may still result in small voids. It may be desirable to perform a deposition process that is not only cheaper (due to the thickness of films that are deposited, such as on the order of at least about 1 μm) but also results in few or no voids.

Because ALD deposits conformally, eventually, during deposition of material in features having small feature openings, when the film grows on sidewalls of the features, the exposed surface of the film on both sidewalls will meet in the center of the feature, causing a seam to be formed because no additional deposition precursors or reactants can fit in the small space between the two sidewall growths. While techniques for surface treatments or other deposition methods could be used to try to mitigate the formation of seams, as devices shrink, it becomes increasingly challenging to fill small features without forming any seams.

Provided herein are methods and apparatus for depositing superconformal films having a high deposition rate using a thermal CVD-enhanced ALD. Certain disclosed embodiments involve overlapping introduction of oxidizing reactants and a precursor reactant in the absence of a plasma within a PEALD cycle. Due to the conformality of the thermal CVD and superconformality of the PEALD, the process is capable of filling medium aspect ratio and high aspect ratio features with tunable conformality to meet gapfill requirements and fill structure void-free. Certain disclosed embodiments may be suitable for depositing films into large gaps, such as 3D-NAND staircase fill where the films deposited fill medium aspect ratio features (about 3:1 to 15:1 or higher) with thick films (usually greater than about 1 μm or as thick as about 3-4 μm). Certain disclosed embodiments address challenges associated with using PECVD or PEALD or ALD alone, as PECVD may cause formation of voids, ALD may be too slow and expensive to be used to deposit such thick oxide films, and PEALD is also expensive with slow throughput and high chemistry usage.

Certain disclosed embodiments involve thermal CVD followed by densification using a plasma. Plasma densification after thermal CVD is further described in PCT Application No. PCT/US21/42562 filed on Jul. 21, 2021 titled “CONFORMAL THERMAL CVD WITH CONTROLLED FILM PROPERTIES AND HIGH DEPOSITION RATE” which is incorporated by reference in its entirety.

Certain disclosed embodiments may be used to deposit material in features having higher aspect ratios or in features with reentrancy in the sidewall profile without forming voids.

Certain disclosed embodiments involve a process which utilizes conformal thermal CVD within a PEALD cycle to enhance the deposition rate and increase precursor utilization to lower the overall cost of the process while forming void-free high quality gapfill films. The superconformality and film properties are tunable. During a PEALD cycle, when the plasma conversion operation is performed, the oxidizing agent may still be present while precursor is subsequently introduced, such that a CVD-like reaction occurs when the deposition precursor is reintroduced. At high temperature (such as at least about 500° C.), this will create a thermal CVD reaction. Combined with the rest of the PEALD cycle, this allows for a PEALD process which is enhanced by some thermal CVD component. This process is suitable for high aspect ratio features. It could also be applied for other applications where a high deposition rate, low cost ALD type film is used with controllable properties. It could also be used in hybrid films such as combined with ALD, PECVD, thermal CVD with plasma densification, and other deposition techniques.

Certain disclosed embodiments can be used in combination with etch operations in a dep-etch-dep process to fill small features.

The use of thermal CVD due to overlap of oxidizer and precursor to enhance the dep rate of a PEALD process while maintaining high step coverage for superconformal gapfill has advantages over some deposition techniques because high quality films can be deposited conformally with a high deposition rate. This results in greater throughput while still maintaining formation of high quality films.

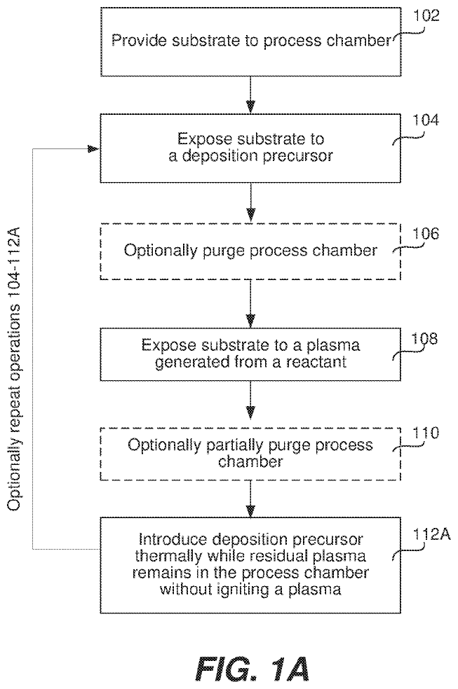

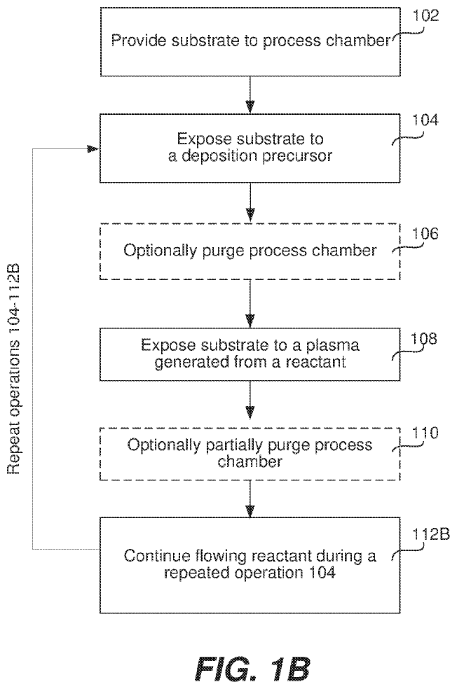

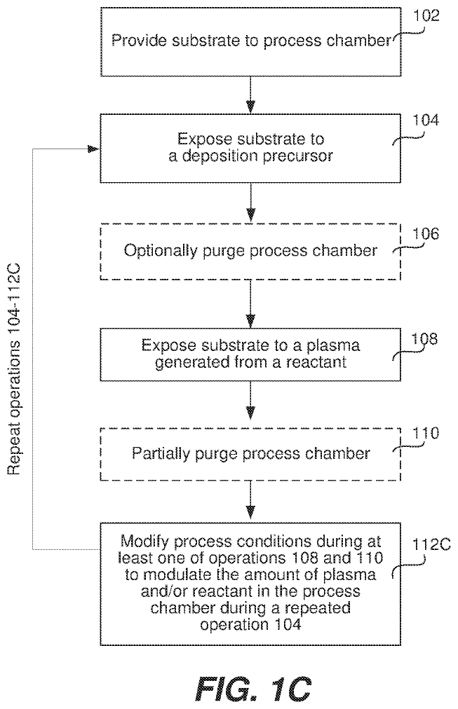

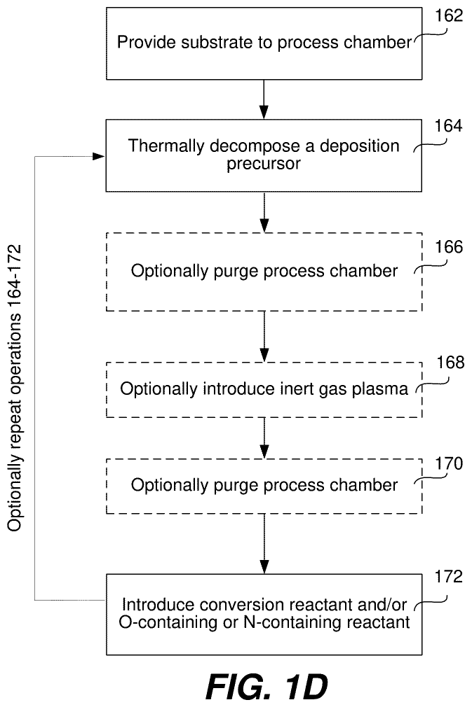

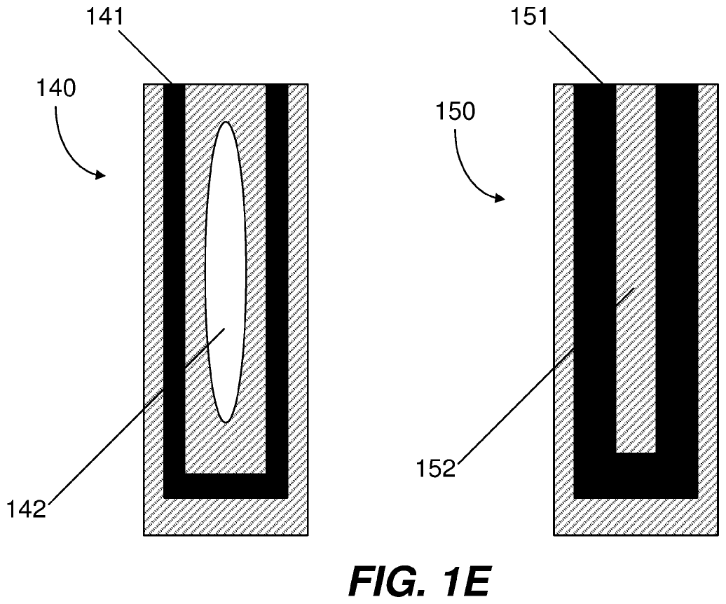

FIG. 1A shows a process flow diagram depicting operations that may be performed in accordance with certain disclosed embodiments. Processes in FIG. 1 may be performed at temperatures of at least about 500° C., or at least about 550° C., or at least about 650° C. It will be understood that substrate temperature as used herein refers to the temperature that the pedestal holding the substrate is set at and that in some embodiments, the substrate when provided to the process chamber on the pedestal may be heated to the desired substrate temperature prior to processing the substrate. In some embodiments, the substrate temperature may also depend on the pressure of the process chamber in which the substrate is housed. The substrate temperature may be the same throughout operations 102-112 as described herein.

In an operation 102, a substrate is provided to a process chamber. In various embodiments, the process chamber is a single-wafer chamber. In some embodiments, the process chamber is a station within a multi-station chamber. Process conditions described herein are suitable for a single-wafer chamber.

The process chamber may be set to a chamber pressure about 5 mTorr to about 25 Torr or about 0.5 Torr to about 25 Torr. Such chamber pressures may be used throughout operations 104-116 as described herein. In some embodiments, chamber pressure may be different during different operations. The chamber pressure may also depend on the chemistries selected for various operations described herein.

The substrate may be any suitable substrate. The substrate may be a silicon wafer, e.g., a 200-mm wafer, a 300-mm wafer, including wafers having one or more layers of material, such as dielectric, conducting, or semi-conducting material deposited thereon. Non-limiting examples of under layers include dielectric layers and conducting layers, e.g., silicon oxides, silicon nitrides, silicon carbides, metal oxides, metal nitrides, metal carbides, and metal layers. In some embodiments, the substrate includes silicon oxide and silicon. In some embodiments, the substrate includes a partially fabricated 3D-NAND structure.

In some embodiments, the feature(s) may have an aspect ratio of at least about 1:1, at least about 2:1, at least about 4:1, at least about 6:1, at least about 10:1, or at least about 20:1, or at least about 50:1, or at least about 100:1, or at least about 150:1, or at least about 200:1, or higher.

The feature(s) may also have a dimension near the opening, e.g., an opening diameter or line width of between about 10 nm to 500 nm, for example between about 25 nm and about 300 nm. Disclosed methods may be performed on substrates with feature(s) having an opening less than about 150 nm. A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier. In various examples, the feature may have a width smaller in the opening at the top of the feature than the width of the bottom of the feature. One or more features may have a high aspect ratio, which is defined as having an aspect ratio of greater than about 100:1 or greater than about 150:1 or greater than about 180:1.

In some embodiments, the substrate may be partially fabricated for forming a memory device. In some embodiments, exposed regions of the substrate include silicon-containing surfaces, including but not limited to low-k dielectric material, silicon oxide, silicon nitride, silicon oxynitride, silicon oxycarbide, silicon carbonitride, and silicon carbide.

In an operation 104, a deposition precursor is introduced. This may be referred to as a “dose.” In various embodiments, the deposition precursor is introduced thermally. Certain disclosed embodiments may be used with a wide variety of deposition precursors, including but not limited to silicon-containing precursors, such as aminosilanes. In various embodiments, the deposition precursor is a silicon-containing precursor.

In various embodiments, the silicon-containing precursor is a silane. Non-limiting examples of silanes that may be used include but are not limited to substituted and unsubstituted silanes, halosilanes, aminosilanes, organosilanes, alkylsilanes, alkylaminosilanes, and alkylhalosilanes. Additional examples of silicon-containing precursors are included elsewhere herein such as in the Definitions and Precursors section

The aminosilane precursor is introduced to provide a precursor for forming the film. In some embodiments, the aminosilane precursor is diisopropylaminosilane (DIPAS).

The aminosilane includes at least one nitrogen atom bonded to a silicon atom, but may also contain hydrogens, oxygens, and carbons. Examples of aminosilanes are mono-, di-, tri- and tetra-aminosilane (H₃Si(NH₂)₄, H₂Si(NH₂)₂, H₂Si(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di(sec-butylamino)silane (DSBAS), di(isopropylamido)silane (DIPAS), bis(diethylamino)silane (BDEAS), and the like. A further example of an aminosilane is trisilylamine (N(SiH₃)₃).

Operation 104 is performed thermally. In various embodiments, operation 104 is performed in a plasma-free environment. In various embodiments, operation 104 is performed without igniting a plasma. In various embodiments, operation 104 is performed without generating a plasma.

Operation 104 may be performed in a temporally separated pulse, separate from other operations in FIG. 1. In some embodiments, operation 104 is performed for a duration of about 0.1 second to about 2 seconds, or about 0.5 second to about 2 seconds, or about 0.1 second to about 0.5 second, or about 0.1 second to about 0.3 second. In various embodiments, the deposition precursor is flowed at a flow rate of at least about 500 sccm or at least about 750 sccm or about 900 sccm for a 4-station process chamber. The deposition precursor may be flowed with a carrier gas which may be an inert gas. In various embodiments, the deposition precursor may be argon, nitrogen, helium, hydrogen, and combinations thereof.

In operation 106, the process chamber is optionally purged. Operation 106 involves stopping flow of the silicon-containing precursor and introducing flow of an inert gas or a purge gas to remove excess silicon-containing precursor molecules that are not adsorbed onto a surface of the substrate or silicon-containing precursor molecules in a processing region of the process chamber over the substrate in gas phase.

Example inert or purge gases include but are not limited to nitrogen gas and argon. Flow rate of the inert or purge gas during operation 106 is about 1000 sccm to about 40000 sccm for a single-wafer chamber. Introduction of the inert or purge gas may be performed for a duration of about 0.1 second to about 10 seconds or about 0.1 second to about 0.5 second. During operation 106, the chamber pressure may be about 0.5 Torr to about 22 Torr. In some embodiments, a lower pressure may be used to purge more effectively. For example, in some embodiments, a pressure of less than about 0.1 Torr or about 0.1 Torr may be used. In some embodiments, the chamber pressure during operation 106 is the same as the chamber pressure used during operation 104. In one example, nitrogen gas is introduced at a flow rate of about 10000 sccm for about 10 seconds at a chamber pressure of about 9.5 Torr. The flow rate, duration, and chamber pressure may depend on the precursor used in operation 106. Operation 106 is performed without igniting a plasma. Operation 106 is performed in a plasma-free environment. In various embodiments, introduction of the deposition precursor may cause the deposition precursor to adsorb or chemisorb onto a surface of the substrate.

In an operation 108, the substrate is exposed to a plasma generated from a reactant. In some embodiments, the reactant is introduced to the process chamber and the plasma is generated in the process chamber. During plasma exposure, the reactant gas may be flowed with one or more inert gases or one or more carrier gases. Example inert gases include hydrogen, helium, argon, and xenon.

In various embodiments, the reactant is an oxygen-containing gas or an oxidizer. Oxygen-containing gases may be used to ignite the plasma, forming an oxidizing plasma. Oxidizers may be used to oxidize the adsorbed or chemisorbed deposition precursor to form silicon oxide. Example oxidizing gases include oxygen, nitrous oxide, carbon dioxide, carbon monoxide, ozone, and peroxides. In some embodiments, a mixture of oxidizing gases may be used, such as a mixture of one or more of oxygen, nitrous oxide, carbon dioxide, carbon monoxide, ozone, and peroxides. In some embodiments, a mixture of oxidizing gases may also include an inert gas, such as argon.

Operation 108 may be performed for a duration of about 0.1 second to about 3 seconds, or about 0.1 second to about 1 second, or about 0.1 second to about 0.6 second, or about 0.1 second to about 0.3 second. Example flow rates of an oxidizer that maybe suitable for a 4-station chamber are about 500 sccm to about 30 L, or about 1 L to about 5 L.

The plasma generated from a reactant may be generated in a remote plasma generator, or may be generated in situ, or in the chamber. “In situ” may refer to being performed in the same chamber. In various embodiments, the plasma is generated using a dual frequency plasma that includes high frequency (HF) radio frequency (RF) plasma and low frequency (LF) RF plasma. In some embodiments, only HFRF plasma is used. In some embodiments, only LFRF plasma is used. HFRF may be generated at a frequency of 13.6 MHz. Example plasma power ranges for HFRF include about 0 kW to about 6 kW for a 4-station chamber. Example plasma power ranges for LFRF include about 0 kW to about 5 kW for a 4-station chamber. In some embodiments, using a higher plasma power may result in more sputtering-like effect at or near the top of the substrate surface.

When the reactant gas is ignited in a plasma, a plasma species is generated. In various embodiments, the plasma species generated formed a reactant plasma ambient in the process chamber in a processing region above a substrate surface. In some embodiments where plasma is generated remotely, the plasma species is introduced to the process chamber to the processing region above a substrate surface. In some embodiments where plasma is generated in situ, the plasma species is generated in the processing region above a substrate surface. In embodiments where a deposition precursor was previously introduced and has adsorbed or chemisorbed onto a substrate surface, the adsorbed or chemisorbed deposition precursor reacts with the plasma species to generate at least a portion of a film on the substrate surface. In some embodiments, the film formed on the substrate surface is silicon oxide.

In some embodiments, after operation 108, the plasma is turned off. In some embodiments, the reactant flow is turned off after operation 108. In some embodiments, the reactant flow is diverted completely after operation 108 to stop flow into the process chamber. In some embodiments, the reactant flow is reduced after operation 108 to reduce flow into the process chamber, but flow is not completely turned off. In some embodiments, both the reactant flow is reduced and the plasma is turned off after operation 108. In some embodiments, after operation 108, some residual amount of the reactant may still be flowed to the process chamber. In some embodiments, the residual amount of reactant flowed to the process chamber is flowed thermally, or without a plasma, or without igniting a plasma, or may have little to no plasma species.

In various embodiments, operations 104 and 108 may constitute one ALD cycle. In various embodiments, operations 104, 106, 108, and 110 may constitute one ALD cycle. In some embodiments, operation 104 is performed prior to operation 108. In some embodiments, operation 108 is performed prior to operation 104. In some embodiments, operations 104 and 108 may be repeated in multiple operations. In some embodiments, operations 104-110 may be repeated in multiple operations. In some embodiments, operations 104 and 108 may be repeated in multiple operations prior to performing operation 112A. In some embodiments, operations 104-110 may be repeated in multiple operations prior to performing operation 112A.

In operation 110, the process chamber is optionally partially purged. In various embodiments, operation 110 is optional. In various embodiments, operation 110 is performed after operation 108. In certain disclosed embodiments, the process chamber is partially purged.

Partial purging refers to purging under process conditions that leaves at least some residual reactants, reactant plasma ambient, or plasma species from operation 108 in the process chamber after operation 110 is performed. Partial purging may result in some species left in the processing region that reacts with a deposition precursor if it is later introduced in repeated cycles.

The process conditions that may be modulated to achieve this effect include but are not limited to: reducing purge time, changing purge gas flow rate(s), not evacuating the chamber, changing the duration in which the chamber is evacuated, eliminating purging as an operation partially or completely, and changing partial pressure of one or more purge gases. In some embodiments, purging is not performed. Where purging is performed, example purge times include but are not limited to: about 0 second to about 1 second; or about 0.05 second to about 1 second; or about 0.05 second to about 0.5 second. The purge gas flow rates may depend on the overall process conditions. Example purge gas flow rates include but are not limited to: about 25 L to about 80 L, or about 25 L to about 70 L, or about 40 L to about 70 L, or about 50 L to about 70 L. In some embodiments, an oxidizer may be continuously flowed; in such embodiments, during purge gas flow, oxidizer may be flowed at a flow rate of about 1 L to about 100 L, or about 1 L to about 20 L, or about 1 L to about 5 L. The partial pressure of purge gases may depend on the operation performed in the processing scheme and may, in some embodiments, change during the purging operation. In some embodiments, the partial pressure of the purge gas is modulated to achieve a particular precursor flow during dose. In some embodiments where oxidizer is flowed during purging as part of continuous flow, the partial pressure of the oxidizer may be about 5% to about 10% of the gas flow. In some embodiments, partial pressure of the oxidizer is about 2% to about 5% where the oxidizer flow is stopped prior to dosing to allow a CVD-like reaction to occur during dose.

In operation 112A, a deposition precursor is introduced thermally while residual plasma remains in the process chamber without igniting a plasma. In various embodiments, this refers to the conditions upon which a repeated operation of operation 104 may be performed. For example, as operations 104 and 108 may be optionally repeated, in repeated operations, operation 104 may be performed under process conditions such that residual plasma from operation 108 in a prior cycle remains in the process chamber, but plasma is not separately generated or ignited in the repeated operation 104.

In various embodiments, the deposition precursor in a repeated operation 104 is introduced thermally. The presence of residual plasma species, residual reactant gas, and/or residual reactant plasma ambient that remains in the process chamber from partially purging in operation 110 when the deposition precursor is introduced results in a thermal CVD-like reaction that can help form additional material on a surface of the substrate, thereby increasing the amount of film deposited in one or more cycles of performing operations in FIG. 1A. This may also result in increased throughput, while still maintaining conformally deposited films by using the cyclic deposition cycles in operations 104 and 108. In various embodiments, the deposition rate is at least about 0.8 Å per cycle or about 0.8 Å to about 3 Å per cycle.

FIG. 1B shows another embodiment that involves various operations that are similar to or the same as that of FIG. 1A. Operations 102, 104, 106, 108, and 110 may be the same as that of FIG. 1A. In FIG. 1B, in operation 112B, the reactant may be continuously flowed during a repeated operation 104. For example, when operations 104 and 108 are repeated in cycles, the subsequent repeated operations of operation 104 may involve flowing the reactant during operation 104. The reactant may be the same as the reactant flowed in operation 108, but without generating a plasma. This results in the presence of the reactant in the process chamber when the substrate is exposed to the deposition precursor in operation 104, thereby causing a thermal CVD-like reaction that can help form additional material on a surface of the substrate, thereby increasing the amount of film deposited in one or more cycles of performing operations in FIG. 1B.

FIG. 1C shows another embodiment that involves various operations that are similar to or the same as that of FIGS. 1A and 1B. Operations 102, 104, 106, 108, and 110 may be the same as that of FIG. 1A. In FIG. 1C, in operation 112C, process conditions during at least one of operations 108 or 110 are modified in to modulate the amount of plasma and/or reactant in the process chamber during a repeated operation 104. In various embodiments, the process conditions are modified such that some residual reactant gas, reactant plasma ambient, or plasma species generated from operation 108 and/or the partial purge operation 110 remains in the process chamber when the substrate is exposed to the deposition precursor in a repeated operation 104, thereby causing a thermal CVD-like reaction. Operation 110 may be modulated to reduce purge time, reduce purge conditions, or even eliminate purging so as to allow residual reactant, reactant plasma ambient, and/or plasma species to remain in the chamber.

It will be understood that while examples in FIGS. 1A-1C show and the corresponding description describes embodiments where a deposition precursor is introduced first, then a plasma is generated from a reactant for an ALD-like reaction, and subsequently residual plasma from operation 108, or from “conversion,” remains when the substrate is exposed to a deposition precursor (or a “dose”), in some embodiments, the reverse may be true—for example, the plasma species may be generated first, but process conditions may be modulated to ensure residual reactant gas, residual reactant plasma ambient, or residual plasma species remain in the chamber, and subsequently, when a deposition precursor is introduced or when a substrate is exposed to the deposition precursor, the precursor reacts with the residual reactant gas, reactant plasma ambient, and/or plasma species to simultaneously form both a CVD-like reaction and an ALD-like reaction to form the film, and such operations may be repeated in multiple cycles. Combinations of and variations of these embodiments may also be used (for example, in some embodiments, every cycle, every other cycle, or every nth cycle, may involve leaving residual reactant, residual plasma ambient, or residual plasma species when exposing to the deposition precursor; in some embodiments, a combination of certain disclosed embodiments and traditional ALD and/or traditional CVD may be used.

In one example, a process may include multiple deposition cycles. In each cycle, a silicon oxide film may be formed using certain disclosed embodiments such that the deposition precursor is a silicon-containing precursor and the reactant is an oxidizer gas. Argon may be an example inert gas that is also used as a purge gas. A deposition cycle may include a silicon-containing precursor exposure phase, a first purge phase, a plasma exposure phase, and a second purge phase.

During the silicon-containing precursor exposure phase, argon flow is on, silicon-containing precursor flow is on, oxidizer flow is off, and plasma is off. This may correspond to operation 104 of FIG. 1A. During the first purge phase, argon flow is on, silicon-containing precursor flow is turned off, oxidizer flow remains off, and plasma remains off. This may correspond to operation 106 of FIG. 1A. During the plasma exposure phase, argon flow is on, silicon-containing precursor flow remains off, oxidizer flow is turned on, and plasma is turned on. This may correspond to operation 108 of FIG. 1A. During the second purge phase, argon flow is reduced to reduce the purging effect (note that other techniques may be used, such as by shortening the purge time but keeping the same flow rate), silicon-containing precursor flow remains off, oxidizer flow is reduced, and plasma is turned off. This may correspond to operation 110 of FIG. 1A. This deposition cycle may be repeated multiple times. In, for example, the second deposition cycle, the cycle may involve a silicon-containing precursor exposure phase, another first purge phase, a plasma exposure phase, and another second purge phase. During the silicon-containing precursor exposure phase, argon flow is on, silicon-containing precursor flow is on, oxidizer flow is off, and plasma is off. This may correspond to a repeated operation 104 of FIG. 1A whereby because the purge performed in the prior cycle was incomplete and still had residual oxidizer on, even though plasma is turned off, some residual oxidizer remains in the process chamber and reacts with the silicon-containing precursor, creating a thermal CVD-like reaction during a repeated ALD cycle. During the first purge phase, argon flow is on, silicon-containing precursor flow is turned off, oxidizer flow remains off, and plasma remains off. This may correspond to operation 106 of FIG. 1A. During the plasma exposure phase, argon flow is on, silicon-containing precursor flow remains off, oxidizer flow is turned on, and plasma is turned on. This may correspond to operation 108 of FIG. 1A. During the second purge phase, argon flow is reduced to reduce the purging effect (note that other techniques may be used, such as by shortening the purge time but keeping the same flow rate), silicon-containing precursor flow remains off, oxidizer flow is reduced, and plasma is turned off. This may correspond to operation 110 of FIG. 1A. Additional cycles, and variations of such cycles, may be further implemented.

In another non-limiting example, a process may include multiple deposition cycles where each cycle has different flows than in the above example. For example, a silicon oxide film may be formed using certain disclosed embodiments such that the deposition precursor is a silicon-containing precursor and the reactant is an oxidizer gas. Argon may be also used as an inert gas that is also used as a purge gas. A first deposition cycle may involve a silicon-containing precursor exposure phase, a first purge phase, a plasma exposure phase, and a second purge phase. During the silicon-containing precursor exposure phase argon flow is on, silicon-containing precursor flow is on, oxidizer flow is off, and plasma is off. This may correspond to operation 104 of FIG. 1B. During the first purge phase, argon flow is on, silicon-containing precursor flow is turned off, oxidizer flow remains off, and plasma remains off. This may correspond to operation 106 of FIG. 1B. During the plasma exposure phase, argon flow is on, silicon-containing precursor flow remains off, oxidizer flow is turned on, and plasma is turned on. This may correspond to operation 108 of FIG. 1B. During the second purge phase, argon flow is reduced to reduce the purging effect (note that other techniques may be used, such as by shortening the purge time but keeping the same flow rate), silicon-containing precursor flow remains off, oxidizer flow is reduced, and plasma is turned off. This may correspond to operation 110 of FIG. 1B.

The deposition cycle may be repeated. The second deposition cycle includes a silicon-containing precursor exposure phase, a first purge phase, a plasma exposure phase, and a second purge phase. During the silicon-containing precursor exposure phase, unlike in the prior deposition cycle, oxidizer flow is turned on, and argon flow is on, silicon-containing precursor flow is on, and plasma is off. This may correspond to a repeated operation 104 of FIG. 1B whereby because oxidizer flow continues to flow in the silicon-containing precursor exposure phase of the second deposition cycle, the oxidizer reacts with the silicon-containing precursor to form a thermal CVD-like reaction during an ALD cycle. During a first purge phase of the second deposition cycle, argon flow is on, silicon-containing precursor flow is turned off, oxidizer flow remains off, and plasma remains off. This may correspond to operation 106 of FIG. 1B. During the plasma exposure phase of the second deposition cycle, argon flow is on, silicon-containing precursor flow remains off, oxidizer flow is turned on, and plasma is turned on. This may correspond to operation 108 of FIG. 1B. During the second purge phase of the second deposition cycle, argon flow is reduced to reduce the purging effect (note that other techniques may be used, such as by shortening the purge time but keeping the same flow rate), silicon-containing precursor flow remains off, oxidizer flow is reduced, and plasma is turned off. This may correspond to operation 110 of FIG. 1B. It will be understood that in some embodiments, the purge phase used in the first deposition cycle may have the same flow of argon but may have no oxidizer on Additional cycles, and variations of such cycles, may be further implemented.

Certain disclosed embodiments may involve modulating RF power, RF time, precursor flow, dose time, and ratio of ALD deposition to CVD deposition. Example HF RF powers include but are not limited to: OW to about 6000 W, or about 1000 W to about 5000 W. Example LF RF powers include but are not limited to OW to about 4000 W, or about 1000 W to about 3000 W. Example RF times include but are not limited to: 0.1 second to about 1 second, or about 0.1 second to about 0.5 second, or about 0.4 second to about 0.6 second. In some embodiments, an RF time of about 0.4 second to about 0.6 second may provide an additional benefit of improving film quality and improving cracking resistance. Example precursor flow rates include but are not limited to: 100 sccm to about 1500 sccm, or about 150 sccm to about 1500 sccm, or about 500 sccm to about 1000 sccm, or about 150 sccm to about 500 sccm, or about 200 sccm to about 500 sccm. The flow rate may also depend on the precursor used. Example dose times include but are not limited to: about 0.05 second to about 0.5 second, or about 0.1 second to about 0.5 second, or about 0.1 second to about 0.2 second, or about 0.05 second to about 0.3 seconds. In some embodiments, precursor flow can be modulated to change the amount of CVD-like reaction that takes place, depending on how much residual reactant is in the process chamber. Likewise, the reactant flow can also be modulated to change the amount of CVD-like reaction that takes place, depending on how much precursor flow is used and other process conditions during conversion. In some embodiments, dose time may be modulated to change the duration of the CVD-like reaction. In some embodiments, the ratio of ALD to CVD deposition may be modulated by changing the number of cycles, the duration of doses and conversions in a cycle, the duration(s) of purge(s) used in cycles, relative flow rates, and other process conditions.

Certain disclosed embodiments form films having a variety of film properties. For example, certain disclosed embodiments form films having superior uniformity. Certain disclosed embodiments form films having certain stress. In some embodiments, the stress may be about −400 MPa to about −250 MPa, or about −350 MPa to about −300 MPa. In some embodiments, films deposited using certain disclosed embodiments may have improved shrinkage. For example, the shrinkage of the deposited film measured at 700° C. for 30 minutes may be less than about 0.5%, or about 0.1% to about 0.5%. In various embodiments, the stress shift measured at 700° C. for 30 minutes may be less than about 15 MPa.

In some embodiments, certain implementations may be integrated with dep-etch-dep processes where certain disclosed embodiments are used for the “dep” operation in a dep-etch-dep process. In a dep-etch-dep process, some material may be initially deposited, the deposited material may be partially etched to open a feature or create a wider opening in the deposited material, or may be exposed to a passivation gas to reduce or slow nucleation of subsequent material, followed by further deposition. Certain disclosed embodiments may be used for at least one or both of the deposition processes in a “dep-etch-dep” process. In some cases, a dep-etch-dep process is performed in multiple cycles. Certain disclosed embodiments may be used for deposition in any one or more cycle in any one or more deposition operation.

Certain disclosed embodiments are suitable for integrating with techniques that involve passivating or preferentially inhibiting deposition on one or more regions of the substrate during deposition, such as in dep-etch-dep applications for filling high aspect ratio features. Certain disclosed embodiments may have increased tolerance in maintaining critical dimension in wafers exhibiting bowing. Certain disclosed embodiments may be utilized in bottom-up fill of low aspect ratio features.

Provided herein are methods of and apparatuses for pyrolyzing a deposition precursor on a surface of a substrate to form at least a partial pyrolyzed layer and/or pyrolyzed material and exposing the pyrolyzed material to one or more plasmas to densify, oxidize, and/or convert the pyrolyzed material into a desired composition. A deposition precursor that is pyrolyzed undergoes pyrolysis. Pyrolysis involves thermal decomposition of a material at a particular elevated temperature. The term “pyrolyzed film” as used herein refers to a film that includes material that was formed by pyrolysis, such as by pyrolyzing a deposition precursor. A pyrolyzed material may not necessarily be fully oxidized when deposited, and in some embodiments, may not be oxidized when deposited, or may not be oxidized at all when deposited. Pyrolysis may be performed in an oxygen-free environment in some embodiments.

Certain disclosed embodiments can be performed in a cyclic fashion such that pyrolysis and exposure to the one or more plasmas are performed in temporally separated pulses. Certain disclosed embodiments involve a modified atomic layer deposition process such that pyrolysis is performed during a dose operation to form more than a monolayer per cycle. Pyrolysis is performed in a deposition reaction that is similar to chemical vapor deposition (CVD) or may pyrolyze thermally onto a substrate surface, but can be integrated into a deposition process having cycles such as in ALD. When the pyrolyzed film is exposed to certain plasmas, the film increases by volume and can fill features without causing the formation of seams. In some embodiments, the pyrolyzed film is subsequently oxidized. Oxidation may cause the film to expand which may be due to incorporation of oxygen. Films deposited using certain disclosed embodiments may also be conformal. In certain embodiments, deposition thickness across surfaces of a substrate, including surfaces within a high aspect ratio negative feature or within horizontal features, is consistent between sidewalls and bottoms of the features.

FIG. 1D shows a process flow diagram depicting operations that may be performed in accordance with certain disclosed embodiments. In operation 162, a substrate is provided to a process chamber. Certain disclosed embodiments are suitable for forming films on a wide variety of substrate surfaces, including but not limited to silicon-containing surfaces, non-metal surfaces, poly-silicon surfaces, dielectric surfaces, oxide surfaces, nitride surfaces, silicon oxide surfaces, silicon nitride surfaces, and the silicon wafer itself.

In various embodiments, the process chamber is a single-wafer chamber. In some embodiments, the process chamber is a station within a multi-station chamber. Process conditions described herein are suitable for a single-wafer chamber.

The process chamber may be set to a chamber pressure about 5 mTorr to about 70 Torr, or about 10 Torr to about 60 Torr, or about 10 Torr to about 40 Torr, or about 30 Torr. Such chamber pressures may be used throughout operations 164-172 as described herein. In some embodiments, chamber pressure may be different during different operations. The chamber pressure may also depend on the chemistries selected for various operations described herein.

The substrate may be heated to a substrate temperature sufficient to pyrolyze the deposition precursor used in operation 164. For example, in some embodiments, the substrate temperature may be at least about 400° C. In various embodiments, the substrate may be heated to any suitable temperature, such as about 25° C. to about 800° C., or about 500° C. to about 700° C., or at least about 400° C. For example, in some embodiments, the deposition precursor may be diisopropylaminosilane, which may be pyrolyzed at a temperature of greater than about 475° C. In various embodiments, various operations may implement different substrate temperatures. It will be understood that substrate temperature as used herein refers to the temperature that the pedestal holding the substrate is set at and that in some embodiments, the substrate when provided to the process chamber on the pedestal may be heated to the desired substrate temperature prior to processing the substrate. The substrate temperature may be the same throughout operations 162-168 as described herein.

The substrate may be any suitable substrate. The substrate may be a silicon wafer, e.g., a 200-mm wafer, a 300-mm wafer, including wafers having one or more layers of material, such as dielectric, conducting, or semi-conducting material deposited thereon. Non-limiting examples of under layers include dielectric layers and conducting layers, e.g., silicon oxides, silicon nitrides, silicon carbides, metal oxides, metal nitrides, metal carbides, and metal layers. In some embodiments, the substrate includes silicon oxide and silicon. In some embodiments, the substrate includes a partially fabricated 3D-NAND structure.

In some embodiments, the feature(s) may have an aspect ratio of at least about 1:1, at least about 2:1, at least about 4:1, at least about 6:1, at least about 10:1, or at least about 20:1, or at least about 50:1, or at least about 100:1, or at least about 150:1, or at least about 200:1, or higher.

The feature(s) may also have a dimension near the opening, e.g., an opening diameter or line width of between about 10 nm to 500 nm, for example between about 25 nm and about 300 nm. Disclosed methods may be performed on substrates with feature(s) having an opening less than about 150 nm. A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier. In various examples, the feature may have a width smaller in the opening at the top of the feature than the width of the bottom of the feature. One or more features may have a high aspect ratio, which is defined as having an aspect ratio of greater than about 100:1 or greater than about 150:1 or greater than about 180:1.

In operation 164, a deposition precursor is pyrolyzed thermally. Pyrolysis is performed thermally. Pyrolysis is performed in a plasma-free environment. The substrate is heated on a pedestal set to a temperature that is at least that of the pyrolysis temperature of the precursor(s) to be used. The pyrolysis precursor may be flowed with one or more inert gases (such as but not limited to helium and/or argon) to the substrate; the heated substrate allows the pyrolysis precursor to pyrolyze onto the surface of the substrate. Pyrolysis may be performed at low chamber pressure such as about 20T or about 60T and less than atmospheric pressure.

Precursors that may be used for pyrolysis include silicon-containing precursors, such as silanes. Silanes include but are not limited to halosilanes, aminosilanes, and organosilanes. In certain embodiments, silicon-containing precursors where the silicon center has one or more thermally cleavable bonds (such as Si—H bonds) may be advantageous to allow pyrolysis at lower temperatures and reduced energy used to cleave substituents and leave a Si-rich film on the surface of the substrate.

Certain disclosed embodiments maybe used with a wide variety of deposition precursors, including but not limited to silicon-containing precursors, non-limiting examples of which are listed in the Definitions and Precursors section. In some embodiments, the silicon-containing precursors are aminosilanes. In some embodiments, the aminosilane precursor is diisopropylaminosilane (DIPAS).

The precursor may be flowed at a flow rate of about 90 sccm or about 850 sccm for a single-wafer chamber. The silicon-containing precursor may be flowed with an inert push gas, such as nitrogen gas or argon gas or a mixture of nitrogen and argon gas. The flow rate of the inert push gas may be about 125 sccm to about 1000 sccm for a single-wafer chamber. Operation 104 may be performed for a duration of about 0.05 second to about 3 seconds. In some embodiments, additional nitrogen gas may be introduced with the silicon-containing precursor and/or the inert push gas for dilution, for pressure stability, or both. The additional nitrogen gas may be flowed at a flow rate of about 250 sccm to about 2500 sccm for a single-wafer chamber.

Pyrolysis is performed such that pyrolysis occurs within the process chamber; that is, while a deposition precursor is flowed through gas lines to the process chamber, pyrolysis occurs in the process chamber but not in the gas lines. In various embodiments, certain disclosed embodiments are implemented in such way that pyrolysis may only occur when a wafer is on the pedestal in the process chamber, or may only occur at or near the pedestal region of the process chamber. Pyrolysis is performed such that the pedestal is set at a temperature that is at least the pyrolysis temperature or greater than the pyrolysis temperature of the precursor(s) used during pyrolysis. Examples include at least about 400° C., or at least about 500° C., or at least about 650° C., or at least about 750° C.

In some embodiments, pyrolysis of the deposition precursor results in a pyrolyzed film or a pyrolyzed material or at least a partial pyrolyzed film on the substrate surface. Where an aminosilane is used, the pyrolyzed or pyrolyzed film may include silicon nitride, silicon carbonitride, silicon oxycarbonitride, or combinations thereof; or may be silicon nitride, silicon carbonitride, silicon oxycarbonitride, or combinations thereof.

In operation 166, the process chamber may be optionally purged. As noted herein, in certain embodiments, purging may be performed between any or all operations, such as after pyrolysis but before inert plasma exposure, or after inert plasma exposure and before oxidizing or nitrogen-containing plasma exposure, or after oxidizing or nitrogen-containing plasma exposure and before repeating any of the above operations, or any number of these operations or all of these operations. Purging may be optional.

Operation 166 involves stopping flow of the silicon-containing precursor and introducing flow of an inert gas or a purge gas to remove excess silicon-containing precursor molecules that are not adsorbed onto a surface of the substrate or silicon-containing precursor molecules in a processing region of the process chamber over the substrate in gas phase.

Example inert or purge gases include but are not limited to nitrogen gas and argon. Flow rate of the inert or purge gas during operation 166 is about 1000 sccm to about 40000 sccm for a single-wafer chamber. Introduction of the inert or purge gas may be performed for a duration of about 0.1 second to about 10 seconds. During operation 166, the chamber pressure may be about 0.5 Torr to about 60 Torr. In some embodiments, a lower pressure may be used to purge more effectively. For example, in some embodiments, a pressure of less than about 0.1 Torr or about 0.1 Torr may be used. In some embodiments, the chamber pressure during operation 166 is the same as the chamber pressure used during operation 164. In one example, nitrogen gas is introduced at a flow rate of about 10000 sccm for about 10 seconds at a chamber pressure of about 9.5 Torr. The flow rate, duration, and chamber pressure may depend on the precursor used in operation 106. Operation 166 is performed without igniting a plasma. Operation 166 is performed in a plasma-free environment.

In operation 168, the substrate is optionally introduced to an additive gas plasma. In some embodiments, the additive gas plasma is an inert gas plasma. Example additive gas plasmas may be used to densify the pyrolyzed material. Example additive gases include hydrogen, helium, argon, nitrogen, and xenon. Additive plasmas may be used to smoothen the surface of the pyrolyzed film, which can allow thickness to be even across the surface. In some embodiments, exposure to an additive plasma can vary the content of the film deposited. For example, in some embodiments, depending on the additive plasma composition, the exposure time, and the plasma power used, carbon content can be reduced. In some embodiments, nitrogen content may be increased by using a nitrogen-containing additive plasma. In some embodiments, oxygen content may be slightly reduced by using certain additive plasmas. In various embodiments, inert gas plasma is performed for every about 1 nm of film deposited on a substrate surface.

The inert gas plasma may be generated by igniting an inert gas in situ, or by igniting an inert gas in remote plasma chamber. In various embodiments, the inert gas is flowed at a flow rate of about 100 sccm to about 15000 sccm for a single-wafer station. The plasma is ignited at a plasma power of about 75 W to about 1500 W for a 13.56 MHz frequency plasma. In various embodiments, operation 108 is performed for a duration of about 0.05 second to about 20 seconds.

The pyrolyzed material remains on the substrate surface during operation 168. During operation 168, some volatile fragments may be ejected from the film to increase the remaining atomic content of silicon, carbon, nitrogen, or any combination thereof.

In operation 170, the process chamber is again optionally purged. Purging may be performed using any one or more of the process gases and conditions described above with respect to operation 166. In one example, nitrogen gas is flowed at a flow rate of about 10000 sccm for about 10 seconds in a chamber having a chamber pressure of about 9.5 Torr.

In operation 142, a conversion reactant is introduced to the process chamber. In some embodiments, the conversion reactant is a conversion reactant plasma, or an oxygen-containing plasma, or a nitrogen-containing plasma, or any combination thereof may be introduced to the process chamber. In various embodiments, the pyrolyzed material is exposed to a conversion reactant plasma such as an oxygen-containing plasma, or a nitrogen-containing plasma. In some embodiments, the conversion reactant is a plasma-free gas or gas mixture.

For embodiments involving plasma. during plasma exposure in operation 162, one or more of the following gases may be used: oxidizing gases, and nitrogen-containing gases. Oxidizing gases may be used to oxidize the pyrolyzed material, such as to form silicon oxide. Example oxidizing gases include oxygen, nitrous oxide, carbon dioxide, ozone, peroxides, alcohols, and water. Water can be formed by combining hydrogen and oxygen gas inside the chamber at an elevated temperature, or can be delivered from an ampoule. Nitrogen-containing gases may be used to form a nitride of the pyrolyzed material, such as to form silicon nitride. Example nitrogen-containing gases include nitrogen gas, ammonia, and deuterated ammonia (ND3). In various embodiments, oxidizing or nitrogen-containing plasmas may be used for every about 5 nm or less of film deposited on a substrate surface. During exposure to an oxidizing plasma or nitrogen-containing plasma, one or more additional inert gases may also be used. In some embodiments, hydrogen may also be used. Hydrogen may also be used to assist with ashing carbon-containing components of the pyrolyzed film, such as if an organosilane is used during pyrolysis and the pyrolyzed film has substantial carbon content. In some embodiments, the plasma may be a dual frequency plasma. A high frequency RF plasma may be generated at a plasma power of about 500 W to about 6000 W. A low frequency RF plasma may be generated at a plasma power of about 500 W to about 4000 W.

For embodiments where operation 162 is performed using a plasma-free process, the pyrolyzed film may be converted to silicon oxide or silicon nitride using plasma-free conversion reactants. For example, in some embodiments, water, alcohols, and/or a mixture of oxygen and hydrogen gas may be used during operation 162.

In some embodiments, a mixture of oxygen and hydrogen gas may involve flowing about 500 sccm to about 20 L of oxygen gas and about 500 sccm to about 20 L of hydrogen gas.

In various embodiments, the nitrogen gas plasma may be used to convert the pyrolyzed film to silicon nitride. In various embodiments, the oxygen gas plasma may be used to convert the pyrolyzed film to silicon oxide. In various embodiments, exposure to plasma in operation 162 expands the volume of the pyrolyzed film and its densified or converted form thereof which can thereby fill gaps, voids, and/or seams formed in the film.

In some embodiments, if an oxygen-containing reactant or reactant plasma is used during operation 162, oxidation may facilitate healing or fusing of seams or voids formed during deposition of the material into negative features. For example, use of an oxygen-containing reactant or oxygen-containing reactant plasma will cause the pyrolytic film to be oxidized, and the incorporation of oxygen may cause the film to expand to heal seams or voids. This may be particularly useful in features having high aspect ratios. In some embodiments, in subsequent operations, a later treatment operation may be performed to cause the film to expand further and to close or seal a seam in features. Oxidation can increase the volume of the pyrolyzed film by about 50% to about 100%.

FIG. 1B shows an example of two schematic illustrations of features before and after oxidation. Feature 140 shows a non-oxidized pyrolytic film layer 141 which may be deposited using certain disclosed embodiments, and a void or seam 142 in the feature. Feature 150 shows the feature 140 after performing an in-situ or ex-situ steam anneal, whereby pyrolytic film layer 151 is now oxidized and has expanded in volume, and the feature no longer has a void as shown in the center 152 of the feature.

During operation 112, the temperature may depend on the reactants being used. In some embodiments, the temperature is about 600° C. to about 1000° C., or about 600° C. to about 850° C. In some embodiments, operation 112 is performed in a different chamber than operation 104 or 108. In some embodiments, operation 112 is performed in the same chamber as operation 104 and/or operation 108.

Operations 104-112 may be optionally repeated in cycles. In some embodiments, operation 106, 108, and 110 are each optionally repeated in each cycle; in some embodiments, repeated cycles may omit any one or more of operations 106, 108, or 110. In some embodiments, operation 112 is performed every less than about 5 nm of pyrolyzed material deposited on a substrate surface. In some embodiments, operation 112 is performed every cycle. In some embodiments, more than about 1 nm of material is formed from pyrolysis. In certain embodiments, silicon-rich films are deposited; the composition of the film deposited can be modulated by selecting specific deposition precursors, inert gases, and oxygen-containing and nitrogen-containing gases during conversion. Operations 104-112 may be performed in any order.

Conformal films can be deposited using certain disclosed embodiments. Certain disclosed embodiments have the unexpected advantage of being conformal despite CVD-like pyrolysis in operation 104. Films having high conformality may have a high step coverage. Conformality of films may be measured by the step coverage. Step coverage may be calculated by comparing the average thickness of a deposited film on a bottom, sidewall, or top of a trench to the average thickness of a deposited film on a bottom, sidewall, or top of a feature or trench. The step coverage may be at least about 85%, or about 85% to about 100%. A “feature” of a substrate may be a via or contact hole, which may be characterized by one or more of narrow and/or re-entrant openings, constrictions within the feature, and a high aspect ratio. High aspect ratio may refer to features having an aspect ratio of at least about 10:1 or at least about 15:1 or at least about 20:1 or at least about 50:1 or at least about 100:1 or at least about 150:1 or at least about 200:1. The terms “trench” and “feature” may be used interchangeably in the present disclosure and will be understood to include any hole, via, or recessed region of a substrate.

Certain disclosed embodiments may be used to deposit a variety of films as pyrolysis of a precursor can be integrated with various processes, such as ALD of silicon oxide, plasma-enhanced chemical vapor deposition (PECVD) of silicon oxide, chemical vapor deposition (CVD) of silicon carbonitride, and others. In various embodiments, use of an aminosilane precursor for pyrolysis in particular can have various advantages. Certain aminosilane precursors may also be more susceptible to being pyrolyzed or pyrolyzed, and can provide a useful foundation for densification and/or conversion for a variety of silicon-containing films to be deposited on substrate surfaces.

Various deposition cycles using certain disclosed embodiments may be implemented. In one example, a deposition cycle that may be repeated includes the following operations: perform temporally alternating pulses of operation 164 and 168 for multiple cycles, followed by performing operation 172. In another example, a deposition cycle that may be repeated includes the following operations: perform temporally alternating pulses of operations 164, 168, and 172. In another example, a deposition cycle that may be repeated includes the following operations: perform operation 164 and 172 in temporally alternating pulses without performing operation 168. In another example, a deposition cycle that may be repeated includes the following operations: perform operation 164 and either operation 168, operation 172, or both, in temporally alternating pulses with at least one purging operation between each of operation 164, 168, and 172. Each deposition cycle may deposit more than one monolayer, such as about 2-3 Å per cycle.

Certain disclosed embodiments have numerous tunable process conditions, allowing the process to be tailored to various different applications. For example, the selection of the deposition precursor, the gases used during plasma exposure, the chamber pressure, the exposure durations, and other process conditions can be tailored to accommodate a desired application. In some embodiments, increasing the chamber pressure may result in higher conformality. In some embodiments, the same chamber pressure is used for operations 164-172. In some embodiments, the chamber pressure in operation 164 is different from operation 168. In some embodiments, the chamber pressure in operation 164 is different from operation 172. In some embodiments, the chamber pressure in operation 108 is different from operation 172. Certain disclosed embodiments may also be used to deposit hermetic films, such as hermetic silicon nitride films.

For example, in some embodiments, certain precursors having more Si—Si and Si—H bonds can be used with lower pyrolysis temperatures. Certain precursors having more Si—Si bonds and more Si—H bonds may also affect the composition of the film (such as by incorporating more Si atoms and/or H atoms).

In another example, certain precursors having more than 2 Si—N linkages may be used with higher onset temperatures for pyrolysis. Films deposited with such precursors may have higher atomic content of nitrogen in the film.

In certain embodiments, increasing the substrate temperature will increase the rate of pyrolysis once the onset temperature for initiating pyrolysis has been reached.

Using certain processing temperatures may also affect the relative atomic content of silicon, carbon, and nitrogen in the film. These can be tailored depending on the desired film composition.

Certain disclosed embodiments may allow deposition of films with controllable composition. For example, the various amounts of silicon, oxygen, carbon, nitrogen, hydrogen, and any other atoms in the deposited film may be varied by varying certain process conditions, selection of the deposition precursor, the gases used during plasma exposure, the chamber pressure, the exposure durations, and other process conditions. This may have incredible advantages over certain other ALD processes that may involve incorporating an additional precursor. Instead, the selection of the appropriate precursor for pyrolysis and gases used for plasma exposure can be used to tailor the film composition.

Certain disclosed embodiments may also result in smoothened substrate surfaces. For example, repeating operation 164 and 168 in multiple cycles may result in material deposited that also has an exposed surface that is smoothened compared to before deposition. For example, in some embodiments, roughness on films deposited into features may be reduced by exposing the pyrolyzed and oxidized film to argon plasma after deposition.

Certain disclosed embodiments may also be used with dep-etch-dep processes for filling features. For example, after forming a film used certain disclosed embodiments, the substrate may be etched to, for example, open a feature opening and allow further deposition into the feature. Certain embodiments may also be used with a passivation gas exposure performed between cycles to preferentially prevent deposition of film at or near a feature opening to allow a bottom-up fill of a feature. In some embodiments, the composition of films deposited using certain disclosed embodiments may be tailored to increase later etch selectivity when using fluorine-containing etching processes. This can be achieved by using an oxidizing plasma treatment following the bulk film deposition using certain disclosed embodiments. In embodiments where a dept-etch-dep gapfill process is implemented, using certain disclosed embodiments can form films where the amount of etching at or near the top of the feature is greater than the amount of etching at the bottom of the feature. In one example, in some embodiments, the composition of the film is tailored to within a trench or hole feature patterned into the substrate such that the relative ratio of carbon to nitrogen is different at the top of the feature as compared to the bottom of the feature, thereby increasing selectivity when etching using fluorine-containing etchants such as nitrogen trifluoride, carbon tetrafluoride, and sulfur hexafluoride, or other fluorocarbons, and when such etchants are used with a high frequency, or a dual frequency (both high frequency and low frequency) plasma.

Certain disclosed embodiments may allow faster deposition due to a higher deposition rate. For example, a cycle of precursor pyrolysis, inert gas plasma, and oxidizing plasma may form a film that is about 2 Å to about 3 Å thick. For example, in some embodiments where the critical dimension is greater than about 500 nm, or where the aspect ratio of a feature is greater than bout 5:1, or in other large area gapfill applications, certain disclosed embodiments may be used to fill such features due to the higher deposition rate. Certain disclosed embodiments may be used to replace or supplement deposition processes that traditionally involved CVD.

Certain disclosed embodiments also can be used to form films having various dopants, which may be introduced during any operation or by using particular deposition precursors or plasmas. Certain disclosed embodiments may form films having silicon oxide, silicon nitride, silicon carbide, silicon oxycarbide, silicon oxynitride, doped variants thereof, or combinations thereof. Carbon and nitrogen doping can be accomplished via the use of a particular precursor, and attenuated with the use of an oxidizing plasma. In some embodiments, the relative amount of nitrogen can be tailored by using one or more nitrogen-containing plasmas and tailoring process conditions used during plasma exposure. Other dopants such as phosphorous and boron can be incorporated by using a third precursor such as triethylphosphate or trimethylborate, respectively.

Certain disclosed embodiments may be used to deposit films into features with lateral recesses. Certain disclosed embodiments may be used for fabricating 3D DRAM structures. Certain disclosed embodiments may be used for filling materials in horizontal structures.

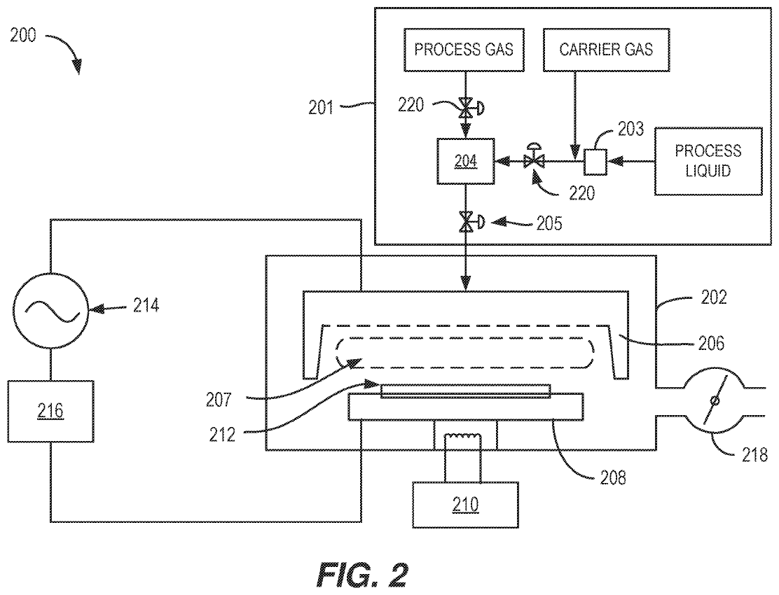

In some embodiments, decomposition of the deposition precursor as described with respect to FIG. 2 can be combined with one or more processes described with respect to FIGS. 1A, 1B, and 1C as described above. For example, at least one of operations 104 and 112A may involve decomposing or pyrolyzing a deposition precursor such as described with respect to operation 164 of FIG. 1D; likewise, the conversion operation of operation 172 of FIG. 1D may be combined with the plasma generation operation 108 of FIGS. 1A, 1B, and 1C, and in some embodiments, when embodiments are combined, operation 112A, 112B, or 112C may be optional or may be performed.

### Apparatus

Certain disclosed embodiments perform such methods in apparatuses with advanced valving to allow introduction of various gases to perform the methods herein.

FIG. 2 schematically shows an embodiment of a process station 200 that may be used to deposit material using atomic layer deposition (ALD) and/or chemical vapor deposition (CVD), either of which may be plasma enhanced. For simplicity, the process station 200 is depicted as a standalone process station having a process chamber body 202 for maintaining a low-pressure environment. However, it will be appreciated that a plurality of process stations 200 may be included in a common process tool environment. Further, it will be appreciated that, in some embodiments, one or more hardware parameters of process station 200, including those discussed in detail below, may be adjusted programmatically by one or more computer controllers.

Process station 200 fluidly communicates with reactant delivery system 201 for delivering process gases to a distribution showerhead 206. Reactant delivery system 201 includes a mixing vessel 204 for blending and/or conditioning process gases for delivery to showerhead 206. One or more mixing vessel inlet valves 220 may control introduction of process gases to mixing vessel 204. Similarly, a showerhead inlet valve 205 may control introduction of process gasses to the showerhead 206.

Some reactants, like BTBAS, may be stored in liquid form prior to vaporization at and subsequent delivery to the process station. For example, the embodiment of FIG. 2 includes a vaporization point 203 for vaporizing liquid reactant to be supplied to mixing vessel 204. In some embodiments, vaporization point 203 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 203 may be heat traced. In some examples, mixing vessel 204 may also be heat traced. In one non-limiting example, piping downstream of vaporization point 203 has an increasing temperature profile extending from approximately 100° C. to approximately 150° C. at mixing vessel 204.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 203. In one scenario, a liquid injector may be mounted directly to mixing vessel 204. In another scenario, a liquid injector may be mounted directly to showerhead 206.

In some embodiments, a liquid flow controller upstream of vaporization point 203 may be provided for controlling a mass flow of liquid for vaporization and delivery to process station 200. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PLD controller.

Showerhead 206 distributes process gases toward substrate 212. In the embodiment shown in FIG. 2, substrate 212 is located beneath showerhead 206, and is shown resting on a pedestal 208. It will be appreciated that showerhead 206 may have any suitable shape, and may have any suitable number and arrangement of ports for distributing processes gases to substrate 212.

In some embodiments, a microvolume 207 is located beneath showerhead 206. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 208 may be raised or lowered to expose substrate 212 to microvolume 207 and/or to vary a volume of microvolume 207. For example, in a substrate transfer phase, pedestal 208 may be lowered to allow substrate 212 to be loaded onto pedestal 208. During a deposition process phase, pedestal 208 may be raised to position substrate 212 within microvolume 207. In some embodiments, microvolume 207 may completely enclose substrate 212 as well as a portion of pedestal 208 to create a region of high flow impedance during a deposition process.

Optionally, pedestal 208 may be lowered and/or raised during portions the deposition process to modulate process pressure, reactant concentration, etc., within microvolume 207. In one scenario where process chamber body 202 remains at a base pressure during the deposition process, lowering pedestal 208 may allow microvolume 207 to be evacuated. Example ratios of microvolume to process chamber volume include, but are not limited to, volume ratios between 1.200 and 1:10. It will be appreciated that, in some embodiments, pedestal height may be adjusted programmatically by a suitable computer controller.

In another scenario, adjusting a height of pedestal 208 may allow a plasma density to be varied during plasma activation and/or treatment cycles included in the deposition process. At the conclusion of the deposition process phase, pedestal 208 may be lowered during another substrate transfer phase to allow removal of substrate 212 from pedestal 208.

While the example microvolume variations described herein refer to a height-adjustable pedestal, it will be appreciated that, in some embodiments, a position of showerhead 206 may be adjusted relative to pedestal 208 to vary a volume of microvolume 207. Further, it will be appreciated that a vertical position of pedestal 208 and/or showerhead 206 may be varied by any suitable mechanism within the scope of the present disclosure. In some embodiments, pedestal 208 may include a rotational axis for rotating an orientation of substrate 212. It will be appreciated that, in some embodiments, one or more of these example adjustments may be performed programmatically by one or more suitable computer controllers.

Returning to the embodiment shown in FIG. 2, showerhead 206 and pedestal 208 electrically communicate with RF power supply 214 and matching network 216 for powering a plasma. In some embodiments, the plasma energy may be controlled by controlling one or more of a process station pressure, a gas concentration, an RF source power, an RF source frequency, and a plasma power pulse timing. For example, RF power supply 214 and matching network 216 may be operated at any suitable power to form a plasma having a desired composition of radical species. Examples of suitable powers are included above. Likewise, RF power supply 214 may provide RF power of any suitable frequency. In some embodiments, RF power supply 214 may be configured to control high- and low-frequency RF power sources independently of one another. Example low-frequency RF frequencies may include, but are not limited to, frequencies between 50 kHz and 200 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 208 may be temperature controlled via heater 210. Further, in some embodiments, pressure control for deposition process station 200 may be provided by butterfly valve 218. As shown in the embodiment of FIG. 2, butterfly valve 218 throttles a vacuum provided by a downstream vacuum pump (not shown). However, in some embodiments, pressure control of process station 200 may also be adjusted by varying a flow rate of one or more gases introduced to process station 200.

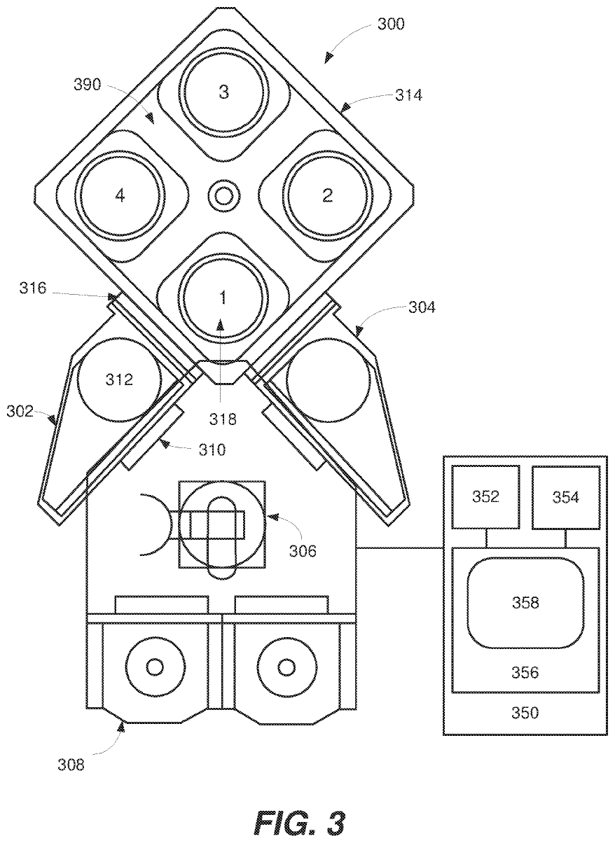

FIG. 3 shows a schematic view of an embodiment of a multi-station processing tool 300 with an inbound load lock 302 and an outbound load lock 304, either or both of which may comprise a remote plasma source. A robot 306, at atmospheric pressure, is configured to move wafers from a cassette loaded through a pod 308 into inbound load lock 302 via an atmospheric port 310. A wafer is placed by the robot 306 on a pedestal 312 in the inbound load lock 302, the atmospheric port 310 is closed, and the load lock is pumped down. Where the inbound load lock 302 comprises a remote plasma source, the wafer may be exposed to a remote plasma treatment in the load lock prior to being introduced into a processing chamber 314. Further, the wafer also may be heated in the inbound load lock 302 as well, for example, to remove moisture and adsorbed gases. Next, a chamber transport port 316 to processing chamber 314 is opened, and another robot (not shown) places the wafer into the reactor on a pedestal of a first station shown in the reactor for processing. While the embodiment depicted in FIG. 3 includes load locks, it will be appreciated that, in some embodiments, direct entry of a wafer into a process station may be provided.

The depicted processing chamber 314 comprises four process stations, numbered from 1 to 4 in the embodiment shown in FIG. 3. Each station has a heated pedestal (shown at 318 for station 1), and gas line inlets. It will be appreciated that in some embodiments, each process station may have different or multiple purposes. While the depicted processing chamber 314 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 3 also depicts an embodiment of a wafer handling system 390 for transferring wafers within processing chamber 314. In some embodiments, wafer handling system 390 may transfer wafers between various process stations and/or between a process station and a load lock. It will be appreciated that any suitable wafer handling system may be employed. Non-limiting examples include wafer carousels and wafer handling robots. FIG. 3 also depicts an embodiment of a system controller 350 employed to control process conditions and hardware states of process tool 300. System controller 350 may include one or more memory devices 356, one or more mass storage devices 354, and one or more processors 352. Processor 352 may include a CPU or computer, analog and/or digital input/output connections, stepper motor controller boards, etc.

In some embodiments, system controller 350 controls all of the activities of process tool 300. System controller 350 executes system control software 358 stored in mass storage device 354, loaded into memory device 356, and executed on processor 352. System control software 358 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 300. System control software 358 may be configured in any suitable way. For example, various process tool component subroutines or control objects may be written to control operation of the process tool components necessary to carry out various process tool processes in accordance with the disclosed methods. System control software 358 may be coded in any suitable computer readable programming language.

In some embodiments, system control software 358 may include input/output control (IOC) sequencing instructions for controlling the various parameters described above. For example, each phase of a PEALD process may include one or more instructions for execution by system controller 350. The instructions for setting process conditions for a PEALD process phase may be included in a corresponding PEALD recipe phase. In some embodiments, the PEALD recipe phases may be sequentially arranged, so that all instructions for a PEALD process phase are executed concurrently with that process phase.

Other computer software and/or programs stored on mass storage device 354 and/or memory device 356 associated with system controller 350 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 318 and to control the spacing between the substrate and other parts of process tool 300.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 350. The user interface may include a display screen, graphical software displays of the apparatus and/or process conditions, and user input devices such as pointing devices, keyboards, touch screens, microphones, etc.

In some embodiments, parameters adjusted by system controller 350 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 350 from various process tool sensors. The signals for controlling the process may be output on the analog and digital output connections of process tool 300. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS® product family, the VECTOR® product family, and/or the SPEED® product family, each available from Lam Research Corp., of Fremont, California, or any of a variety of other commercially available processing systems. Two or more of the stations may perform the same functions. Similarly, two or more stations may perform different functions. Each station can be designed/configured to perform a particular function/method as desired.

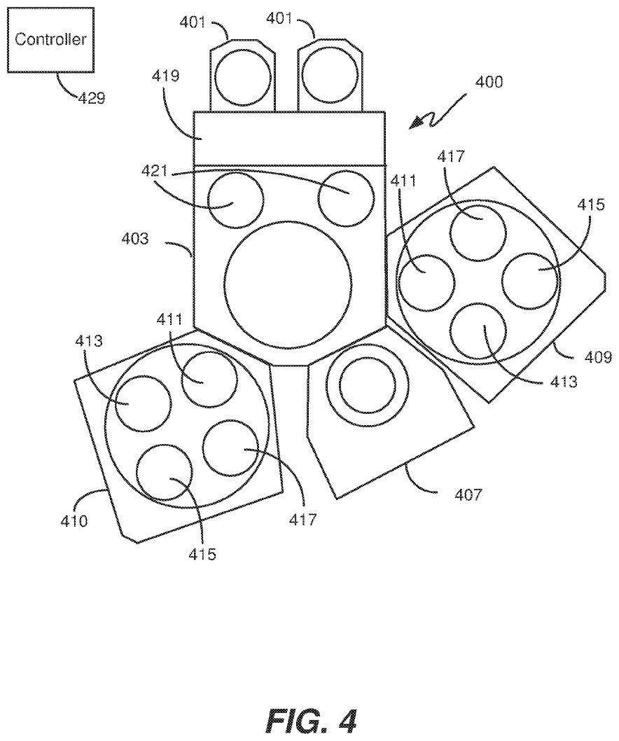

FIG. 4 is a block diagram of a processing system suitable for conducting thin film deposition processes in accordance with certain embodiments. The system 400 includes a transfer module 403. The transfer module 403 provides a clean, pressurized environment to minimize risk of contamination of substrates being processed as they are moved between various reactor modules. Mounted on the transfer module 403 are two multi-station reactors 409 and 410, each capable of performing atomic layer deposition (ALD) and/or chemical vapor deposition (CVD) according to certain embodiments. Reactors 409 and 410 may include multiple stations 411, 413, 415, and 417 that may sequentially or non-sequentially perform operations in accordance with disclosed embodiments. The stations may include a heated pedestal or substrate support, one or more gas inlets or showerhead or dispersion plate.

Also mounted on the transfer module 403 may be one or more single or multi-station modules 407 capable of performing plasma or chemical (non-plasma) pre-cleans, or any other processes described in relation to the disclosed methods. The module 407 may in some cases be used for various treatments to, for example, prepare a substrate for a deposition process. The module 407 may also be designed/configured to perform various other processes such as etching or polishing. The system 400 also includes one or more wafer source modules 401, where wafers are stored before and after processing. An atmospheric robot (not shown) in the atmospheric transfer chamber 419 may first remove wafers from the source modules 401 to loadlocks 421. A wafer transfer device (generally a robot arm unit) in the transfer module 403 moves the wafers from loadlocks 421 to and among the modules mounted on the transfer module 403.

In various embodiments, a system controller 429 is employed to control process conditions during deposition. The controller 429 will typically include one or more memory devices and one or more processors. A processor may include a CPU or computer, analog and/or digital input/output connections, stepper motor controller boards, etc.

The controller 429 may control all of the activities of the deposition apparatus. The system controller 429 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 429 may be employed in some embodiments.

Typically there will be a user interface associated with the controller 429. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 429. The signals for controlling the process are output on the analog and digital output connections of the deposition apparatus 400.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 429 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 429, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Experimental

### Experiment 1

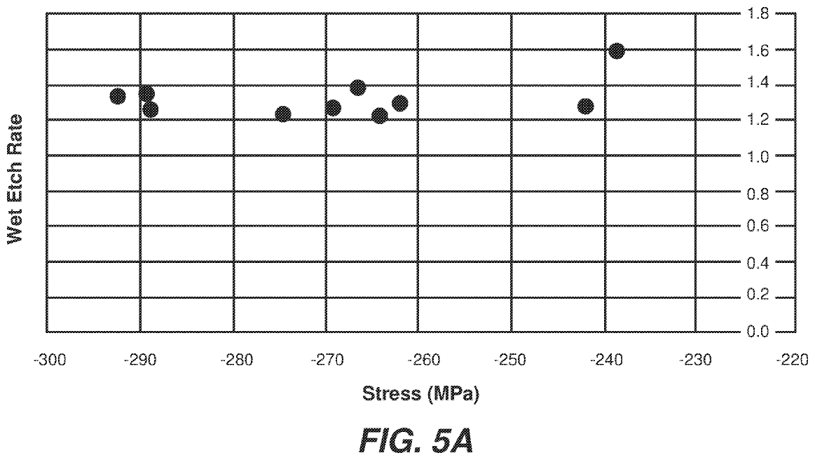

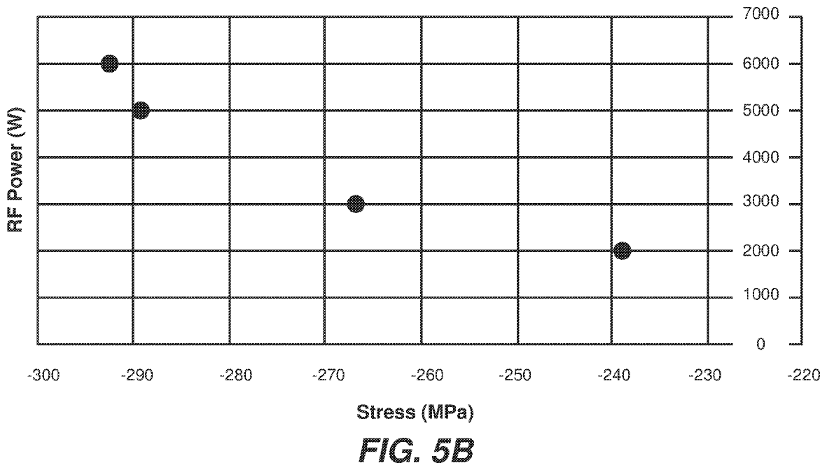

Stress and wet etch rate was measured for a film deposited by introducing a deposition precursor thermally, introducing a reactant with plasma, and introducing the deposition precursor without a plasma while some plasma from the prior operation remained in the chamber. Stress was plotted against RF power. Results in FIGS. 5A and 5B suggest that stress can be tuned while maintaining wet etch rate using RF power, RF time, and other process conditions.

### Experiment 2

An experiment involved depositing a film by pyrolysis, measuring the thickness of the film deposited, then exposing the pyrolyzed film to in-situ plasma oxidation and measuring the thickness of the film after in-situ plasma oxidation. The results are shown in Table 1.

TABLE 1
Volume Expansion of Silicon Oxide
Films after Oxidation Plasma

| | Thickness before | Thickness after | % |
|---|---|---|---|
| | oxidation (nm) | oxidation (nm) | increase |
| Top | 3.31 | 4.01 | 21.3% |
| at 25% | 3.06 | 4.05 | 32.4% |
| at 50% | 3.14 | 3.91 | 24.3% |
| at 75% | 3.06 | 3.68 | 20.3% |
| Bottom | 3.67 | 4.40 | 19.9% |

### Experiment 3

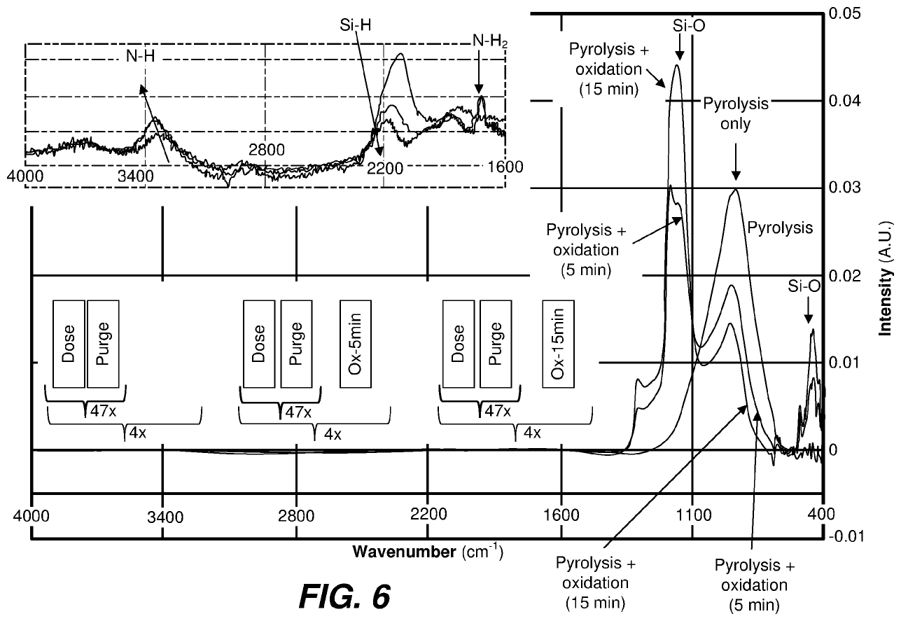

A silicon oxide film was deposited by pyrolysis using certain disclosed embodiments (e.g., 4 overall cycles of performing (1) 47 cycles of pyrolysis and purge, and (2) performing in-situ oxidation plasma). The FTIR is shown in FIG. 6, showing that the film having undergone in-situ oxidation plasma treatment resulted in increased Si—O bonds, reduced Si—H bonds, and saturated N—H₂ and N—H bonds at low oxidation time.

### Experiment 4

Four layers of silicon oxide were deposited using pyrolysis on a semiconductor substrate in accordance with certain disclosed embodiments. Prior to oxidation, the film had a thickness of about 22 nm. Following an oxidation performed using a plasma-free in situ mixture of hydrogen and oxygen gas at a temperature of about 650° C., the pyrolytic film expanded to a thickness of about 33 nm. These results suggested the volumizing ability of using certain disclosed embodiments which can be useful for sealing seams in high aspect ratio features.

### Experiment 5

An experiment was conducted for depositing films by pyrolysis using diisopropylaminosilane (DiPAS) as a deposition precursor and using no additive plasma, an additive plasma generated from only argon, an additive plasma generated from a mixture of argon and hydrogen, and an additive plasma generated from a mixture of argon and ammonia. The XPS results for the film deposited using each of these process conditions is provided in Table 2.

TABLE 2
XPS Results for Various Silicon-Containing Films

| | Plasma | Plasma | XPS results | | | |
|---|---|---|---|---|---|---|
| Precursor | Gas | time | Si | C | N | O |
| DiPAS | No plasma | | 48.8 | 26.8 | 15.0 | 9.4 |
| DiPAS | Ar | 1000 W/1 s | 42.3 | 1.1 | 49.4 | 7.1 |
| DiPAS | Ar/H₂ | 1000 W/1 s | 42.1 | 0.7 | 50.1 | 7.1 |
| DiPAS | Ar/NH₃ | 1000 W/1 s | 43.1 | 0 | 49.7 | 7.2 |

### Definitions and Precursors

### Definitions

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ is aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₀₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₂, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl: (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17)N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22)—CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23)—C(O)NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (24)—SO₂R₁, where R¹ is selected from the group consisting of (a) C₁₋₆ alkyl, (b) C₄₋₁₈ aryl, and (c) C₄₋₄s aryl-C₁₋₆ alkyl (e.g., -L-R, in which L is C₁₋₆ alkyl and R is C₄₋₁₈ aryl); (25)—SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₄s aryl); and (26)—NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₈, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₄₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-Ct-12 alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein; and each of R; and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane n-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C1. alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31)N-protected amino; (32)N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36)—(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₄-a aryl-C₁₋₆ alkyl (e.g., -L-R, in which L is C₁₋₆ alkyl and R is C₄₋₁₈ aryl); (37)—(CH₂), CONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38)—(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39)—(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40)—(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₄₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₆ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). In some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₆₋₁₀, C₆₋₁₈, C₆₋₁₄, C₆₋₁₂, or C_{6.10} arylene group. The arylene group can be branched or unbranched. The arylene group can also be substituted or unsubstituted.

For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-Ns, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl.

Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}— group, in which each of R^{s1}, R^{S2}, R^{S3}, R⁴, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —C4 group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof: or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(Rr)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR¹)R^{Ak}, or —C(NR^{N1})R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S. M. et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like, other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR′R²R³ or —SiR′R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

As used herein, the term “about” means +/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Other features and advantages of the invention will be apparent from the following description and the claims.

### Silicon-Containing Precursors

In various embodiments, the silicon-containing precursor is a silane. Silanes include but are not limited to substituted and unsubstituted silanes, halosilanes, aminosilanes, organosilanes, alkylsilanes, alkylaminosilanes, and alkylhalosilanes. In particular embodiments, the silicon-containing precursor includes a halosilane precursor. In particular embodiments, the silicon-containing precursor includes an aminosilane precursor.

An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, H₂Si(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di(sec-butylamino)silane (DSBAS), di(isopropylamino)silane (DIPAS), bis(diethylamino)silane (BDEAS), and the like. A further example of an aminosilane is trisilylamine (N(SiH₃)₃). In one example, the silicon-containing precursor is DIPAS. In another example, the silicon-containing precursor is BTBAS.

A silicon-containing precursor can include one or more optionally substituted amino groups, thereby providing a non-limiting amino silane. In one embodiment, the precursor has a formula of (R¹)₄₋ₓ Si(NR″₂)x, wherein.
x is 1, 2, 3, or 4;
each R¹ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of

(R″₂N)ₓ(R¹)₃₋ₓSi-L-Si(R′)₃₋ₓ(NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R¹ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In particular embodiments, at least one R′ or R″ is not H. The precursor can have any useful combination of R¹ groups and amino groups (NR″₂) attached to one or more silicon atoms.

In some embodiments, R¹ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or tBu). In other embodiments, R″ is —SiR′₃, —SiR₃, —Si(R)ₐ(OR)_{b}, —Si(R)ₐ(OR)_{b}, —Si(R¹)ₐ(NR₂)_{b}, —Si(R)ₐ(NR₂)_{b}, —Si(R¹)ₐ(OR)_{b}(NR₂)_{c}, —Si(R)ₐ(OR)_{b}(NR₂)_{c}, —O—SiR′₃, —O—SiR₃, —O—Si(R¹)ₐ(OR)_{b}, —O—Si(R)ₐ(OR)_{b}, —O—Si(R¹)ₐ(NR₂), —O—Si(R)ₐ(NR₂)_{b}, —O—Si(R)ₐ(OR)_{b}(NR₂)_{c}, or —O—Si(R)ₐ(OR)_{b}(NR₂)_{c} in which each R¹ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include at least one R¹ group attached to the silicon atom. In one embodiment, the precursor has a formula of (R¹)(H)₃₋ₓSi(NR″₂)_{b}, wherein R′ and R″ can be any described herein, and wherein x is 1, 2, or 3. In another embodiment, the precursor has a formula of (R′)(H)₂Si(NR″₂), wherein R′ and R″ can be any described herein. In one embodiment, the precursor has a formula of (R′)(H)Si(NR″₂)₂, wherein R′ and R″ can be any described herein. In another embodiment, the precursor has a formula of (R¹)₂(H)Si(NR″₂), wherein R′ and R″ can be any described herein. In yet another embodiment, the precursor has a formula of (R¹)₂Si(NR″₂)₂, wherein R′ and R″ can be any described herein. In one embodiment, the precursor has a formula of (R¹)₃Si(NR″₂), wherein R′ and R″ can be any described herein.

The precursor can lack an R¹ group attached to the silicon atom. In one embodiment, the precursor has a formula of (H)₄₋ₓSi(NR″₂)ₓ, wherein each R″ can independently be any described herein, and wherein x is 1, 2, 3, or 4. In another embodiment, the precursor has a formula of Si(NR″₂)r, wherein each R″ can independently be any described herein. In particular embodiments, each R″ is, independently, aliphatic, heteroaliphatic, aromatic, or heteroaromatic.

The precursor can include one or more hydrogen atoms attached to the silicon atom. In one embodiment, the precursor has a formula of (H)₃Si(NR″₂) or (H)₂Si(NR″₂)₂ or (H)Si(NR″₂)₃, wherein each R″ can independently be any described herein. In particular embodiments, each R″ is, independently, aliphatic, heteroaliphatic, aromatic, heteroaromatic, or amino, in which any of these may be optionally substituted.

The precursor can include a heterocyclyl group having a nitrogen atom. In one embodiment, the formula has a formula of H₃Si-Het, in which Het is an optionally substituted heterocyclyl including at least one nitrogen atom. In particular embodiments, the precursor has a formula of

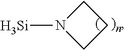

in which the heterocyclyl group can be optionally substituted (e.g., with any substituent described herein as a substitution for alkyl), and wherein n is 1,2, 3, 4, or 5. In one embodiment, the formula has a formula of R′₃Si-Het, in which Het is an optionally substituted heterocyclyl including at least one nitrogen atom, and each R¹ can independently be any described herein. In particular embodiments, the precursor has a formula of

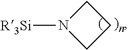

in which the heterocyclyl group can be optionally substituted (e.g., with any substituent described herein as a substitution for alkyl); each R¹ can independently be any described herein; and wherein n is 1,2, 3, 4, or 5.

In some instances, the precursor can have two or more silicon atoms, in which the precursor can include a Si—Si bond. In a particular embodiment, the precursor has a formula of (R″₂N)ₓ(R¹)₃₋ₓSi—Si(R¹)₃₋ₓ(NR″₂)ₓ, wherein R′ and R″ can be any described herein. In one embodiment, the precursor has a formula of (R″₂N)(R¹)₂Si—Si(R¹)₂(NR″₂), wherein R′ and R″ can be any described herein. In another embodiment, the precursor has a formula of (R¹ 2N)₂(R¹)Si—Si(R¹)(NR″₂)₂, wherein R′ and R″ can be any described herein. In yet another embodiment, the precursor has a formula of (R″₂N)₃Si—Si(NR″₂)₃, wherein each R″ can independently be any described herein.

The precursor can include differing groups attached to the silicon atoms. In one instance, the precursor has a formula of (R″₂N)ₓ(R¹)₃₋ₓSi—SiH₃, wherein R′ and R″ can be any described herein.

A linker can be present between two silicon atoms. In one instance, the precursor has a formula of (R″₂N)ₓ(R¹)₃—.Si—NR—Si(R¹)₃₋ₓ(NR″₂)ₓ, wherein R′ and R″ can be any described herein, and in which R is H, optionally substituted aliphatic, optionally substituted alkyl, optionally substituted alkenyl, optionally substituted alkynyl, or optionally substituted aromatic. In another instance, the precursor has a formula of (R″₂N)ₓ(H)₃₋ₓSi—NR—Si(H)₃₋ₓ(NR″₂)ₓ, wherein R, R′, and R″ can be any described herein.

The precursor can include a combination of R¹ groups with a linker having a heteroatom. In one instance, the precursor has a formula of (R¹)₃Si—NR—Si(R¹)₃, wherein R and R′ can be any described herein. In another instance, the precursor has a formula of (R¹)₃Si-L-Si(R¹)₃, wherein L and R¹ can be any described herein. In particular embodiments, L is oxy (—O—), optionally substituted imino (e.g., —NR—), or optionally substituted silyl (e.g., —SiR₂—).

The precursor can include any useful combination of R¹ and NR″₂ groups in combination with two silicon atoms. In one instance, the precursor has a formula of (R″₂N)(R¹)₂Si-L-Si(R¹)₂(NR″₂)ₓ, wherein L, R¹, and R″ can be any described herein.

The precursor can include heterocyclic groups including the silicon and nitrogen atoms. In one embodiment, the precursor has a formula of

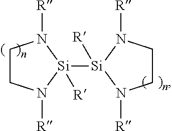

wherein R′ and R″ can be any described herein, and wherein n is 1, 2, 3, or 4.

In another embodiment, the precursor has a formula of

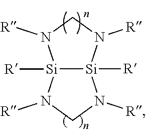

wherein R¹ and R″ can be any described herein, and wherein n is 1, 2, 3, or 4. In yet another embodiment, the precursor has a formula of

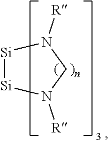

in which each R″ can independently be any described herein; and wherein n is 1,2, 3, or 4.
In another embodiment, the precursor has a formula of

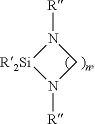

wherein R′ and R″ can be any described herein, and wherein n is 1, 2, 3, or 4. In yet another embodiment, the precursor has a formula of

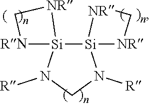

wherein R″ can independently be any described herein, and wherein n is 1, 2, 3, or 4.

In any precursor herein, two R″ can be taken together, with the nitrogen atom to which each is attached, to form an optionally substituted heterocyclyl.

Precursors can include any of the following, e.g., (R^{Ak})Si(NH₂)(NR^{Ak}₂)₂, (R^{Ak})Si(NR^{Ak}₂)₃, (R^{Ak})₂Si(NHR^{Ak}₂)₂, (R^{Ak})(H)Si(NHR^{Ak})₂, (R^{Ak})₃Si(NR^{Ak}₂), (R^{Ak})₃Si(NHR^{Ak}), H₂Si(NHR^{Ak})₂, (R^{Ak})(H)Si(NR^{Ak}₂)₂, H₂Si(NH₂)(NR^{Ak}₂)₂, H₂Si(NR^{Ak}₂)₃, Si(NR^{Ak}₂)₄, (R¹)(H)Si(NR″₂)₂, (R¹)₂Si(NR^{Ak}₂)₂, (R¹)₂Si(N[SiH_{3]2})₂, (R¹)₂Si(N[SiR″_{3]2})₂, or (R¹)₃Si(NHR^{Ak}). In some embodiments, each of R¹ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R^{Ak} is, independently, H, optionally substituted aliphatic, optionally substituted heteroaliphatic, optionally substituted alkyl, optionally substituted alkenyl, or optionally substituted alkynyl. In particular embodiments, R^{Ak} is methyl (Me), ethyl (Et), n-propyl (nPr), iso-propyl (iPr), n-butyl (nBu), sec-butyl (sBu), iso-butyl (iBu), tert-butyl (tBu), and the like.

Non-limiting examples of precursor include any of the following: methylaminotrimethylsilane (SiMe₃[NHMe]); dimethylaminodimethylsilane (SiMe₂H[NMe₂]); dimethylaminotrimethylsilane (SiMe₃[NMe₂]); dimethylaminodiethylsilane (SiHEt₂[NMe₂]); dimethylaminotriethylsilane (SiEt₃[NMe₂]); ethylmethylaminodimethylsilane (SiHMe₂[NMeEt]); ethylmethylaminotrimethylsilane (SiMe₃[NMeEt]); ethylmethylaminodiethylsilane (SiHEt₂[NMeEt]); ethylmethylaminotriethylsilane (SiEt₃[NMeEt]); diethylaminomethylsilane (SiH₂Me[NEt₂]); diethylaminoethylsilane (SiH₂Et[NEt₂]); ethylaminotrimethylsilane (SiMe₃[NHEt]); diethylaminodimethylsilane (SiHMe₂[NEt₂]); diethylaminodiethylsilane (SiHEt₂[NEt₂]); diethylaminotrimethylsilane (SiMe₃[NEt₂]); diethylaminotriethylsilane (SiEt.[NEt₂]); iso-propylaminodimethylsilane (SiHMe₂[NHiPr]); iso-propylaminotrimethylsilane (SiMe₃[NHiPr]); iso-propylaminodiethylsilane (SiHEt₂[NHiPr]); iso-propylaminotriethylsilane (SiEt₃[NHiPr]); di-isopropylaminotrimethylsilane (SiMe₃[NiPr₂]); di-iso-propylaminosilane (SiH₃[NiPr₂], C₆H₁₇NSi, or DIPAS); di-iso-propylaminomethylsilane (SiH₂Me[NiPr₂]); di-isopropylaminodimethylsilane (SiHMe₂[NiPr₂]); di-isopropylaminodiethylsilane (SiHEt₂[NiPrz]); di-isopropylaminotriethylsilane (SiEt₃[NiPr₂]); n-propylaminotrimethylsilane (SiMe₃[NHnPr]); di-sec-butylaminosilane (SiH₃[NsBu₂] or DSBAS); di-sec-butylaminomethylsilane (SiH₂Me[NsBu₂]); iso-butylaminotrimethylsilane (SiMe₃[NHiBu]); n-butylaminotrimethylsilane (SiMe₃[NHnBu]); tert-butylaminodimethylsilane (SiHMe₂[NHtBu]); tert-butylaminotrimethylsilane (SiMe₃[NHtBu]); tert-butylaminodiethylsilane (SiHEt₂[NHtBu]); tert-butylaminotriethylsilane (SiEt₃[NHtBu]); dicyclohexylaminosilane (SiH₃[NCy₂], in which Cy is cyclohexyl); N-propylisopropylaminosilane (SiH₃[NiPrnPr]); N-methylcyclohexylaminosilane (SiH₃[NMeCy]); N-ethylcyclohexylaminosilane (SiH₃[NEtCy]); allylphenylaminosilane (SiH₃[NAllPh]); N-isopropylcyclohexylaminosilane (SiH₃[NiPrCy]); allylcyclopentylaminosilane (SiH₃[NAllCp]); phenylcyclohexylaminosilane (SiH₃[NPhCy]); cyclohexylaminotrimethylsilane (SiMe₃[NHCy], in which Cy is cyclohexyl); pyrrolyltrimethylsilane (SiMe₃[NHPy], in which Py is pyrrolyl); pyrrolidinotrimethylsilane (SiMe₃[NHPyr], in which Pyr is pyrrolindyl); piperidino trimethylsilane (SiMe₃[NHPip], in which Pip is piperidinyl); piperazinotrimethylsilane (SiMe₃[NHPz], in which Pz is piperazinyl); imidazolyltrimethylsilane (SiMe₃[NHIm], in which Im is imidazolyl); bis(dimethylamino)silane (SiH₂[NMe₂]2 or BDMAS); bis(dimethylamino) methylsilane (SiMeH[NMe₂]2); bis(dimethylamino)dimethylsilane (SiMe₂[NMe₂]2 or BDMADMS); bis(dimethylamino)diethylsilane (SiEt₂[NMe₂]2); bis(dimethylamino) methylvinylsilane (SiMeVi[NMe₂]2); bis(ethylamino)dimethylsilane (SiMe₂[NHEt]₂); bis(ethylmethylamino)silane (SiH₂[NMeEt]₂); bis(ethylmethylamino)dimethylsilane (SiMe₂[NMeEt]₂); bis(ethylmethylamino)diethylsilane (SiEt₂[NMeEt]₂); bis(ethylmethylamino) methylvinylsilane (SiMeVi[NMeEt]₂); bis(diethylamino)silane (SiH₂[NEt₂]2, CsH₂₂N₂Si, or BDEAS); bis(diethylamino)dimethylsilane (SiMe₂[NEt₂]2); bis(diethylamino)methylvinylsilane (SiMeVi[NEt₂]2); bis(diethylamino)diethylsilane (SiEt₂[NEt₂]2); bis(iso-propylamino) dimethylsilane (SiMe₂[NHiPr]₂); bis(iso-propylamino)diethylsilane (SiEt₂[NHiPr]₂); bis(iso-propylamino)methylvinylsilane (SiMeVi[NHiPr]₂); bis(di-iso-propylamino)silane (SiH₂[NiPr₂]2); bis(di-iso-propylamino)dimethylsilane (SiMe₂[NiPr₂]2); bis(di-iso-propylamino) diethylsilane (SiEt₂[NiPr₂]2); bis(di-iso-propylamino)methylvinylsilane (SiMeVi[NiPr₂]2); bis(methylamino)silane (SiH₂[NHMe]₂); bis(sec-butylamino)silane (SiH₂[NHsBu]₂); bis(sec-butylamino)methylsilane (SiHMe[NHsBu]₂); bis(sec-butylamino)ethylsilane (SiHEt[NHsBu]₂); bis(tert-butylamino)silane (SiH₂[NHtBu]₂ or BTBAS); bis(tert-butylamino)dimethylsilane (SiMe₂[NHtBu]₂); bis(tert-butylamino) methylvinylsilane (SiMeVi[NHtBu]₂); bis(tert-butylamino)diethylsilane (SiEt₂[NHtBu]₂); bis(1-imidazolyl)dimethylsilane (SiMe₂[Im]₂, in which Im is imidazolyl); tris(dimethylamino)silane (SiH[NMe₂]3 or 3DMAS); tris(dimethylamino)phenylsilane (SiPh[NMe₂]3); tris(dimethylamino) methylsilane (SiMe[NMe₂]3); tris(dimethylamino)ethylsilane (SiEt[NMe₂]3); tris(ethylmethylamino)silane (SiH[NEtMe]₃); tris(diethylamino)silane (SiH[NEt₂]3); tris(iso-propylamino)silane (SiH[NHiPr]₃, C₉H₂₅N₃Si, or TIPAS); tris(dimethylamino)silylamide (Si[NMe₂]3[NH₂]); tetrakis(dimethylamino)silane (Si[NMe₂]4); tetrakis(ethylmethylamino)silane (Si[NEtMe]₄); tetrakis(diethylamino)silane (Si[NEt₂]4); 1,2-diethyl-tetrakis(diethylamino) disilane ([Et₂N]₂EtSi-SiEt[NEt₂]2); 1,2-dimethyl-tetrakis(dimethylamino)disilane ([Me₂N]₂MeSi-SiMe[NMe₂]2); 1,2-dimethyl-tetrakis(diethylamino)disilane ([Et₂N]₂MeSi-SiMe[NEt₂]2); hexakis(methylamino)disilane ([MeHN]₃Si—Si[NHMe]₃); hexakis(ethylamino)disilane ([EtHN]₃Si—Si[NHEt]₃); hexakis(dimethylamino)disilazane (Me₂N—Si[NMe₂]2—Si[NMe₂]2—NMe₂), and the like.

In some embodiments, the silane precursor is a halosilane precursor. A halosilane precursor is defined as a precursor having at least one halogen-containing atom and at least one silicon atom. Halogens include chlorine, fluorine, bromine, and iodine. In some embodiments, the halosilane precursor includes a structure of formula (I):

Si(X)₄,
wherein at least one X includes a halogen atom.

For example, one halosilane is tetrachlorosilane or silicon tetrachloride (SiCl₄). Another example of a chemical formula of a halosilane is SiₙX_{y}H_{z} where X is a halogen and H is hydrogen; n is an integer greater than or equal to 1 and is equal to the number of Si atoms in the molecule; in some embodiments, y is about 1 to about 4, and z is 4-y. Additional examples include but are not limited to SiHCl₃, SiH₂Cl₂, and SiH₃Cl.

Examples of halosilanes are iodosilanes, bromosilanes, chlorosilanes and fluorosilanes. Specific chlorosilanes include but are not limited to tetrachlorosilane, trichlorosilane, dichlorosilane (DCS), monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, hexachlorodisilane (HCDS), and the like.

In some embodiments, the halosilane is carbon-free. In some embodiments, the halosilane is an organic silicon-containing precursor.

In some embodiments, the halosilane precursor (e.g., in formula (I)) has at least one optionally substituted C₁₋₂ haloalkyl group. Non-limiting haloaliphatic groups include —CX_{y}H_{3-y}, wherein y is 1, 2, or 3, and wherein each X is, independently, halo (F, Cl, Br, or 1); —CXₜH_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; or —CH₂CX_{y}H_{3-y}, wherein y is 1, 2, or 3, and wherein each X is, independently, halo (F, Cl, Br, or 1). Yet other non-limiting haloalkyl groups include fluoromethyl (—CH₂F), difluoromethyl (—CHF₂), trifluoromethyl (—CF₃), chloromethyl (—CH₂Cl), dichloromethyl (—CHCl₂), trichloromethyl (—CC₃), bromomethyl (—CH₂Br), dibromomethyl (—CHBr₂), tribromomethyl (—CBr₃), iodomethyl (—CH₂I), diiodomethyl (-CH₂), triiodomethyl (—C₁₃), bromofluoromethyl (—CHFBr), chlorofluoromethyl (—CHFCI), fluoroiodomethyl (—CHFI), 2-fluoroethyl (—CH₂CH₂F), 2-chloroethyl (—CH₂CH₂Cl), 2-bromoethyl (—CH₂CH₂Br), 2-iodoethyl (—CH₂CH₂I), 2,2-difluoroethyl (—CH₂CHF₂), 2,2-dichloroethyl (—CH₂CHCl₂), 2,2-dibromoethyl (—CH₂CHBr₂), 2,2-diiodoethyl (—CH₂CHI₂), 2,2-fluoroiodoethyl (—CH₂CHFI), and the like. In particular embodiments, the C₁₋₂ haloalkyl includes D-halo-substituted ethyl. Yet other haloaliphatic groups include C₁₋₄ haloalkyl, C₂₋₄ haloalkenyl, and C₂₋₄ haloalkynyl.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for processing substrates, the method comprising:
pyrolyzing a deposition precursor on a surface of a substrate to form a pyrolyzed film; and
exposing the pyrolyzed film to a first plasma to form a deposited film.

2. The method of claim 1, wherein the pyrolyzing is performed by heating the substrate to a temperature sufficient to cause pyrolysis of the deposition precursor; and exposing the surface of the substrate to the deposition precursor.

3. The method of claim 1, wherein the pyrolyzing and the exposing of the pyrolyzed film are performed in a process chamber having a chamber pressure of about 10 Torr to about 60 Torr.

4. The method of claim 1, wherein exposing the pyrolyzed film to the first plasma comprises exposing the pyrolyzed film to an inert gas plasma and then exposing the pyrolyzed film to an oxygen-containing or nitrogen-containing plasma.

5. A method for processing substrates, the method comprising:
setting a temperature of a heatable pedestal holding a substrate to a first temperature;
exposing the substrate to a deposition precursor having a pyrolysis temperature that is less than the substrate temperature while the pedestal is heated to the first temperature in a plasma-free environment;
stopping exposure of the deposition precursor; and
after stopping exposure of the deposition precursor, exposing the substrate to a first plasma to form a deposited film.

6. The method of claim 1, wherein the deposition precursor is di(isopropylamino)silane or bis(tertiarybutylamino)silane.

7. The method of claim 1, further comprising exposing the pyrolyzed film to a second plasma.

8. The method of claim 1, wherein the first plasma is generated by igniting an inert gas and the deposited film is densified.

9. (canceled)

10. A method of processing a substrate, the method comprising:
(a) introducing a deposition precursor to a process chamber housing the substrate;
(b) introducing a plasma to the process chamber, the plasma being generated from igniting a reactant to form a reactant plasma ambient in the process chamber; and
(c) while the reactant plasma ambient is in the process chamber, introducing the deposition precursor to the process chamber to form at least a partial film on the substrate.
